(19) United States
(12) Patent Application Publication
(10) Pub. No.: US 2025/0349724 A1
(43) Pub. Date: Nov. 13, 2025

(54) METHOD AND STRUCTURE FOR A BRIDGE INTERCONNECT

(71) Applicant: Taiwan Semiconductor Manufacturing Co., Ltd., Hsinchu (TW)

(72) Inventors: Ming-Fa Chen, Taichung (TW); Min-Chien Hsiao, Taichung (TW); Chih-Chia Hu, Taipei (TW); Han-Ping Pu, Taichung (TW); Ching-Yu Huang, Baoshan Township (TW); Chen-Sheng Lin, Taoyuan (TW); Sung-Feng Yeh, Taipei (TW); Chao-Wen Shih, Zhubei (TW)

(21) Appl. No.: 19/276,355

(22) Filed: Jul. 22, 2025

Related U.S. Application Data
(62) Division of application No. 17/698,121, filed on Mar. 18, 2022.
(60) Provisional application No. 63/249,861, filed on Sep. 29, 2021.
(60) Provisional application No. 63/251,099, filed on Oct. 1, 2021.

(51) Int. Cl. H01L 23/538; H01L 21/56; H01L 23/31; H01L 25/00; H01L 25/065

(52) U.S. Cl. CPC H01L 23/5381; H01L 21/56; H01L 23/3128; H01L 25/0652; H01L 25/50

(57) ABSTRACT

Embodiments utilize a bridge die that directly bonds to and bridges two or more device dies. Each of the device dies can have additional device dies stacked thereupon. In some embodiments, the bridge die can bridge device dies disposed both under and over the bridge die. In some embodiments, several bridge dies may be used to bridge a device die to other adjacent device dies.

### PRIORITY CLAIM AND CROSS-REFERENCE

This application is a divisional of U.S. patent application Ser. No. 17/698,121, filed Mar. 18, 2022, which claims the benefit of U.S. Provisional Application No. 63/251,099, filed Oct. 1, 2021 and U.S. Provisional Application No. 63/249,861, filed Sep. 29, 2021, which applications are hereby incorporated herein by reference.

### BACKGROUND

The packages of integrated circuits are becoming increasing complex, with more device dies packaged in the same package to achieve more functions. For example, System on Integrate Chip (SoIC) has been developed to include a plurality of device dies such as processors and memory cubes in the same package. The SoIC can include device dies formed using different technologies and have different functions bonded to the same device die, thus forming a system. This may save manufacturing cost and optimize device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a package structure in an intermediate step in accordance with some embodiments.

FIG. 2 illustrates a top down view of a package component with multiple device dies defined within.

FIGS. 3 through 4 illustrate cross-sectional views of intermediate stages in the formation of a package component in accordance with some embodiments of the present disclosure.

FIGS. 5 through 6 illustrate cross-sectional views of intermediate stages in the formation of a package component in accordance with some embodiments of the present disclosure.

FIGS. 7 through 8 illustrate cross-sectional views of intermediate stages in the formation of a bridge component in accordance with some embodiments of the present disclosure.

FIGS. 9 through 20 illustrate intermediate stages for forming a package structure having a bridge die utilized therein, in accordance with some embodiments.

FIGS. 21 through 23 illustrate intermediate steps for forming a package device including a different bridge die, in accordance with some embodiments.

FIGS. 24 through 26 illustrate intermediate steps for forming a package device including a different bridge die, in accordance with some embodiments.

FIGS. 27 through 29 illustrate intermediate steps for forming a package device including a different bridge die, in accordance with some embodiments.

FIGS. 30, 31A, and 31B illustrate various configurations for the bridge die and device dies, in accordance with some embodiments.

FIGS. 32 through 34 illustrate intermediate steps in the formation of a quad cross-linked bridge die and device structure, in accordance with some embodiments.

FIG. 35 illustrates a quad cross-linked bridge die, in accordance with other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Silicon bridges may be used to electrically couple metal features from one semiconductor chip to another semiconductor chip. For example, a silicon bridge may provide an electrical path from a first external connector of the silicon bridge to a second external connector of the silicon bridge. The first connector may then be connected, for example, by a solder bump to a first chip and the second connector may be connected to a second chip, thereby forming a bridge between the first chip and the second chip. One issue with such a silicon bridge is that the connection path between the chips and the silicon bridge may have a resistance which causes signal loss, increased energy consumption, and increased waste heat generation.

Embodiments provide several configurations for a silicon bridge die which is directly bonded to the target semiconductor chips, thereby providing increased performance as measured by increased connector density, decreased energy consumption, decreased waste heat production, and increased signal throughput, providing the ability to used higher speed signals between the target chips. Embodiments provide the ability to utilize a local silicon interconnect as a silicon bridge, an integrated passive device die as a silicon bridge, an active device die as a silicon bridge, and/or a photonic die as a silicon bridge. Embodiments also provide the ability to utilize a silicon bridge to connect more than two such as three, four, five, or six, etc. dies together. Embodiments may also be used to provide multiple silicon bridges together in a single package to connect multiple dies to one another. Additional dies may also be used in conjunction with the silicon bridges to provide increased flexibility and functionality.

The embodiments discussed herein are discussed in the context of a System on Integrate Chip (SoIC) package and the method of forming the same, although it should be understood that the disclosed techniques and devices may be used in other packaging contexts. The intermediate stages of forming the SoIC package are illustrated in accordance with some embodiments. Some variations of some embodiments are discussed. Throughout the various views and illustrative embodiments, like reference numbers are used to designate like elements. It is appreciated that although the formation of SoIC packages is used as examples to explain the concept of the embodiments of the present disclosure, the embodiments of the present disclosure are readily applicable to other bonding methods and structures in which metal pads and vias are bonded to each other.

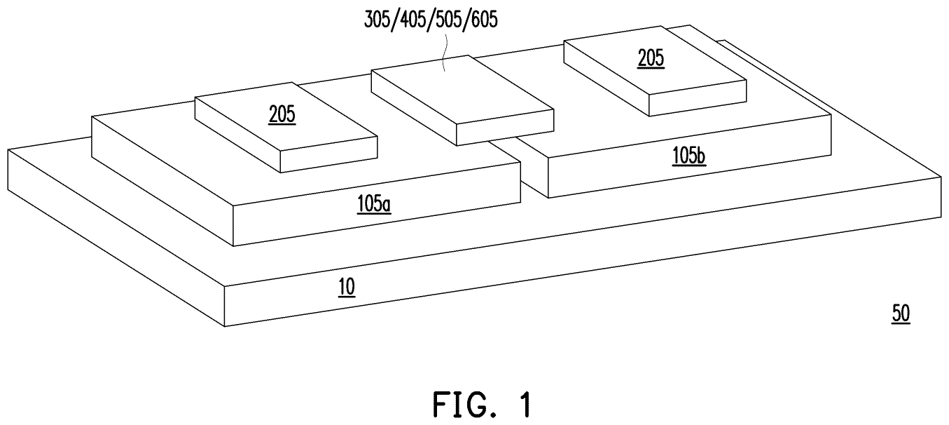

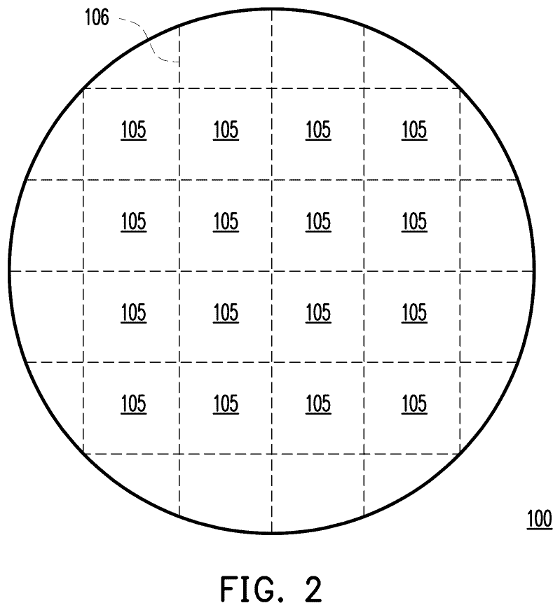

FIG. 1 illustrates a perspective view of an SoIC package device in an intermediate step in accordance with some embodiments. While some examples of types of device dies 105 and 205 are listed below, the device dies 105 and 205 may be any dies. The device die 105 may be a logic die, such as a Central Processing Unit (CPU) die, a Micro Control Unit (MCU) die, an input-output (IO) die, a BaseBand (BB) die, an Application processor (AP) die, or the like. The device die 105 may also be a memory die such as a Dynamic Random Access Memory (DRAM) die or a Static Random Access Memory (SRAM) die, or the like. The device die 105 may be part of a wafer (see FIG. 2). The device die 205 is electrically bonded to the device die 105. The device die 205 may be a logic die, which may be a CPU die, MCU die, IO die, Base-Band die, or AP die. The device die 205 may also be a memory die. Multiple device dies 205 may be bonded to the device die 105, each one having different functionality.

The silicon bridge die 305/405/505/605 is bonded to a first device die 105a and a second device die 105b and bridges a connection between the first device die 105a and the second device die 105b. Different configurations for each of the silicon bridge dies 305/405/505/605 are discussed in further detail below. In some embodiments, multiples of the silicon bridge dies 305/405/505/605 may be used in various combinations of the bridge die 305, bridge die 405, bridge die 505, and bridge die 605.

FIG. 2 illustrates a package component 100 (which may be a wafer, as illustrated) with multiple device dies 105 defined or formed within. The device dies 105 may all be of the same design and function or may be of different designs and functions. The dashed lines represent dicing lines 106 where the device dies 105 will be separated from each other in a subsequent singulation process.

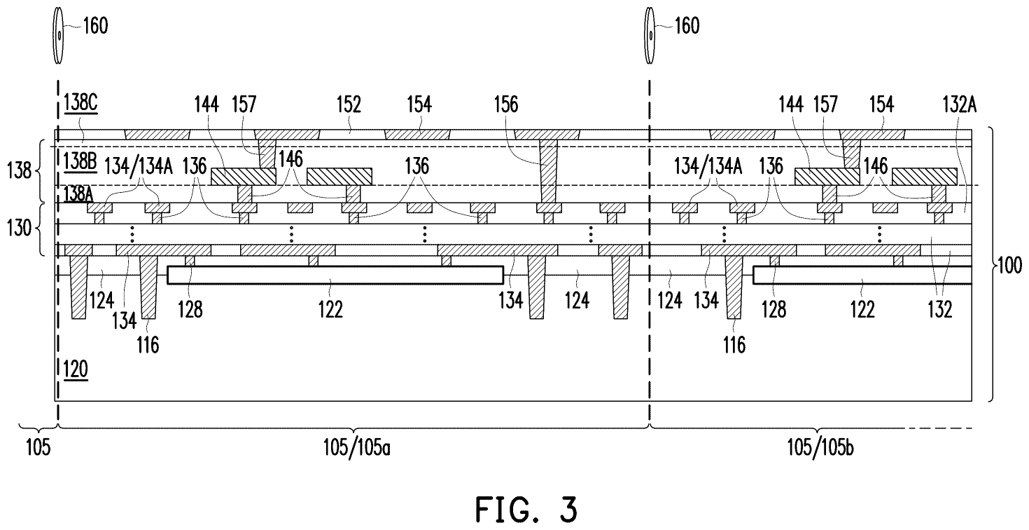

FIGS. 3 through 5 illustrate cross-sectional views of intermediate stages in the formation of an SoIC package in accordance with some embodiments of the present disclosure. FIG. 3 illustrates the cross-sectional view in the formation of package component 100. In accordance with some embodiments of the present disclosure, package component 100 is a portion of a device wafer including integrated circuit devices 122, e.g., active devices such as transistors and/or diodes, and possibly passive devices such as capacitors, inductors, resistors, or the like. Package component 100 may include a plurality of device dies 105 therein, with a portion of device die 105a and a portion of device die 105b illustrated. It should be understood that these views are merely illustrative and not limiting.

In accordance with other embodiments of the present disclosure, package component 100 includes passive devices (with no active devices). In some embodiments, and as referenced in the discussion below, package component 100 may be a device wafer. The embodiments of the present disclosure may also be applied to other types of package components such as interposer wafers.

In accordance with some embodiments of the present disclosure, the wafer 100 includes semiconductor substrate 120 and the features formed at a top surface of semiconductor substrate 120. Semiconductor substrate 120 may be formed of crystalline silicon, crystalline germanium, crystalline silicon germanium, and/or a III-V compound semiconductor such as GaAsP, AlInAs, AlGaAs, GaInAs, GaInP, GaInAsP, and the like. Semiconductor substrate 120 may also be a bulk silicon substrate or a Silicon-On-Insulator (SOI) substrate. Shallow Trench Isolation (STI) regions (not shown) may be formed in semiconductor substrate 120 to isolate the active regions in semiconductor substrate 120. Optional through-vias 116 may be formed to extend into semiconductor substrate 120, and the optional through-vias 116 may be used to electrically inter-couple features on opposite sides of wafer 100.

In accordance with some embodiments of the present disclosure, wafer 100 includes integrated circuit devices 122, which are formed on the top surface of semiconductor substrate 120. Example integrated circuit devices 122 may include Complementary Metal-Oxide Semiconductor (CMOS) transistors, resistors, capacitors, diodes, and/or the like. The details of integrated circuit devices 122 are not illustrated herein. In accordance with other embodiments, wafer 100 is used for forming interposers, in which semiconductor substrate 120 may be a semiconductor substrate or a dielectric substrate.

Inter-Layer Dielectric (ILD) 124 is formed over semiconductor substrate 120, and fills the space between the gate stacks of transistors (not shown) in integrated circuit devices 122. In accordance with some embodiments, ILD 124 is formed of Phospho Silicate Glass (PSG), Boro Silicate Glass (BSG), Boron-Doped Phospho Silicate Glass (BPSG), Fluorine-Doped Silicate Glass (FSG), Tetra Ethyl Ortho Silicate (TEOS) formed silicon oxide, or the like. ILD 124 may be formed using spin coating, Flowable Chemical Vapor Deposition (FCVD), Chemical Vapor Deposition (CVD), Plasma Enhanced Chemical Vapor Deposition (PECVD), Low Pressure Chemical Vapor Deposition (LPCVD), or the like.

Contact plugs 128 are formed in ILD 124, and are used to electrically connect integrated circuit devices 122 to overlying metal lines 134 and vias 136. In accordance with some embodiments of the present disclosure, contact plugs 128 are formed of a conductive material selected from tungsten, aluminum, copper, titanium, tantalum, titanium nitride, tantalum nitride, alloys thereof, and/or multi-layers thereof. The formation of contact plugs 128 may include forming contact openings in ILD 124, filling a conductive material(s) into the contact openings, and performing a planarization (such as Chemical Mechanical Polish (CMP) process) to level the top surfaces of contact plugs 128 with the top surface of ILD 124.

Over ILD 124 and contact plugs 128 resides interconnect structure 130. Interconnect structure 130 includes dielectric layers 132, and metal lines 134 and vias 136 formed in dielectric layers 132. Dielectric layers 132 are alternatively referred to as Inter-Metal Dielectric (IMD) layers 132, hereinafter. In accordance with some embodiments of the present disclosure, at least the lower ones of dielectric layers 132 are formed of a low-k dielectric material having a dielectric constant (k-value) lower than about 3.0 or about 2.5. Dielectric layers 132 may be formed of Black Diamond (a registered trademark of Applied Materials), a carbon-containing low-k dielectric material, Hydrogen SilsesQuioxane (HSQ), MethylSilsesQuioxane (MSQ), or the like. In accordance with alternative embodiments of the present disclosure, some or all of dielectric layers 132 are formed of non-low-k dielectric materials such as silicon oxide, silicon carbide (SiC), silicon carbo-nitride (SiCN), silicon oxy-carbo-nitride (SiOCN), or the like. In accordance with some embodiments of the present disclosure, the formation of dielectric layers 132 includes depositing a porogen-containing dielectric material, and then performing a curing process to drive out the porogen, and hence the remaining dielectric layers 132 becomes porous. Etch stop layers (not shown), which may be formed of silicon carbide, silicon nitride, or the like, may be formed between IMD layers 132, and are not shown for simplicity.

Metal lines 134 and vias 136 are formed in dielectric layers 132. The metal lines 134 at a same level may be collectively referred to as a metal layer hereinafter. In accordance with some embodiments of the present disclosure, interconnect structure 130 includes a plurality of metal layers that are interconnected through vias 136. Metal lines 134 and vias 136 may be formed of copper or copper alloys, and they can also be formed of other metals. The formation process may include single damascene and dual damascene processes. In a single damascene process, a trench is first formed in one of dielectric layers 132, followed by filling the trench with a conductive material. A planarization process such as a CMP process is then performed to remove the excess portions of the conductive material higher than the top surface of the IMD layer, leaving a metal line in the trench. In a dual damascene process, both a trench and a via opening are formed in an IMD layer, with the via opening underlying and connected to the trench. The conductive material is then filled into the trench and the via opening to form a metal line and a via, respectively. The conductive material may include a diffusion barrier and a copper-containing metallic material over the diffusion barrier. The diffusion barrier may include titanium, titanium nitride, tantalum, tantalum nitride, or the like.

Metal lines 134 include metal lines 134A, which may be referred to as top metal lines. Top metal lines 134A are also collectively referred to as being a top metal layer. The respective dielectric layer 132A may be formed of a non-low-k dielectric material such as Un-doped Silicate Glass (USG), silicon oxide, silicon nitride, or the like. Dielectric layer 132A may also be formed of a low-k dielectric material, which may be selected from the similar materials of the underlying IMD layers 132.

In accordance with some embodiments of the present disclosure, dielectric layers 138 and dielectric bonding layers 152 are formed over the top metal lines 134A. Dielectric layers 138 and dielectric bonding layer 152 may be formed of silicon oxide, silicon oxynitride, silicon oxy-carbide, or the like, and in some embodiments dielectric layer 138 may be formed of multiple dielectric sub-layers 138A, 138B, and 138C, for example. First, dielectric sub-layer 138A may be formed. Via openings corresponding to vias 146 may next be formed in the dielectric sub-layer 138A using a photo lithographic process using, for example, photo resists and/or hard masks which are formed and patterned over dielectric sub-layer 138A to aid the formation of via openings corresponding to the vias 146. An anisotropic etch may be used to form these trenches through the photo resists and/or hard masks.

Vias 146 and metal features 144 may be formed over the dielectric sub-layer 138A. Vias 146 and metal features 144 may be formed by processes similar to the formation of vias 136 and metal lines 134, described above, though other suitable process may be used. Metal features 144 and vias 146 may be formed of copper or copper alloys, and they can also be formed of other metals. In an embodiment, the metal features 144 and/or vias 146 may be formed of aluminum or an aluminum copper alloy. In some embodiments, the metal features 144 may be used for die testing.

In some embodiments, the metal features 144 may be directly probed for performing chip probe (CP) testing of the wafer 100. Optionally, solder regions (e.g., solder balls or solder bumps) may be disposed on the metal features 144 and the solder regions may be used to perform CP testing on the wafer 100. CP testing may be performed on the wafer 100 to ascertain whether the each device die 105 of wafer 100 is a known good die (KGD). Thus, only device dies 105 which are KGDs undergo subsequent processing for packaging, and dies which fail the CP testing are not packaged. After testing, the solder regions (if any) may be removed in subsequent processing steps.

The dielectric sub-layer 138B may then be deposited over the metal features 144 up to a desired thickness. In some embodiments, the dielectric sub-layer 138B may then be planarized to level the top surface, while in other embodiments, the leveling step may be omitted. In some embodiments, the dielectric sub-layer 138C is then deposited. Other embodiments may not use the dielectric sub-layer 138C and it may be omitted.

Next, bond pad vias 156 and bond pad vias 157 may be formed. Bond pad vias 156 extend through the entire dielectric layer(s) 138 to the interconnect structure 130 and bond pad vias 157 extend to the metal features 144 and electrically couple thereto. Openings for the bond pad vias 156 and bond pad vias 157 may be formed using photo resists (not shown) and/or hard masks (not shown) which are formed and patterned over dielectric layer 138 to aid the formation of the openings for the bond pad vias 156 and bond pad vias 157. In accordance with some embodiments of the present disclosure, an anisotropic etch is performed to form the openings. The etch may stop on either the metal feature 144 for bond pad vias 157 or on the metal lines 134 of interconnect structure 130 for bond pad vias 156.

The openings for the bond pad vias 156 and the bond pad vias 157 may next be filled with conductive materials. A conductive diffusion barrier (not shown) may be formed first. In accordance with some embodiments of the present disclosure, the conductive diffusion barrier may be formed of titanium, titanium nitride, tantalum, tantalum nitride, or the like. The conductive diffusion barrier may be formed, for example, using Atomic Layer Deposition (ALD), Physical Vapor Deposition (PVD), or the like. The conductive diffusion barrier may include a layer in the openings for the bond pad vias 156 and the bond pad vias 157 and a layer extending over the upper surface of the dielectric layer 138.

Next, a metallic material is deposited to form the bond pad vias 156 and the bond pad vias 157, for example, through Electro-Chemical Plating (ECP) or another suitable deposition process. The metallic material is deposited on the conductive diffusion barrier and fills the remaining openings for the bond pad vias 156 and the bond pad vias 157. The metallic material may also extend over the top surface of the dielectric layer 138. The metallic material may include copper or copper alloy. The bond pad vias 156 and bond pad vias 157 may be formed simultaneously.

A planarization process such as a Chemical Mechanical Polish (CMP) process may then be performed to remove excess portions of the metallic material and the diffusion barrier, until dielectric layer 138 is exposed. The remaining portions of the diffusion barrier and metallic material include bond pad vias 156 and bond pad vias 157.

Next, a dielectric bonding layer 152 may be formed over the dielectric layer 138 and openings formed therein for bond pads 154. The openings may be formed using photo resists (not shown) and/or hard masks (not shown) which are formed and patterned over dielectric bonding layer 152 to aid the formation of the openings for the bond pads 154. In accordance with some embodiments of the present disclosure, an anisotropic etch or wet etch is performed to form the openings for the bond pads 154. The etch may stop on dielectric sub-layer 138C, which may function as an etch stop, in some embodiments. In other embodiments the dielectric bonding layer 152 may have etch selectivity with the dielectric layer 138, so that the dielectric layer 138 is not etched through after the dielectric bonding layer 152 is etched through. In some embodiments, the etch may be time based. The openings for the bond pads 154 may expose upper surfaces of the bond pad vias 156 and bond pad vias 157.

Next, a diffusion barrier and metallic material may be deposited in the openings to form the bond pads 154. Forming the bond pads 154 may use processes and materials similar to those used to form the bond pad vias 156 and bond pad vias 157, described above. A planarization process such as a Chemical Mechanical Polish (CMP) process may then be performed to remove excess portions of the metallic material and the diffusion barrier, until the dielectric bonding layer 152 is exposed. The remaining portions of the diffusion barrier and metallic material include bond pads 154 which are subsequently used for bonding to another device. It is appreciated that metal lines may also be formed simultaneously as bond pads 154.

In some embodiments, the bond pad vias 156 and 157 may be formed at the same time as the bond pads 154. In such embodiments, after the dielectric bonding layer 152 is formed, openings are made in the dielectric bonding layer 152, as described above. Then, further openings are made in the dielectric layer 138 for the bond pad vias 156 and bond pad vias 157, as described above. Then, the conductive diffusion barrier and metallic material may be formed, as described above, for both the bond pad vias 156 and 157 and the bond pads 154 in the same process. Afterwards, a planarization process such as a CMP process may be used to remove excess portions of the metallic material and the diffusion barrier, until the dielectric bonding layer 152 is exposed. The remaining portions of the diffusion barrier and metallic material include bond pads 154 which are subsequently used for bonding to another device. Metal lines running in the same layer as the bond pads 154 may also be formed simultaneously as bond pads 154.

The location and number of bond pads 154 may be adjusted based on the devices which are to be bonded to them in subsequent processes. In some embodiments, one or more of the bond pads 154 may not be electrically connected to any devices in the device die 105. Such bond pads 154 may be considered dummy bond pads. In some embodiments, dummy bond pads 154 may continue across the surface of the device die 105, while in other embodiments, bond pads 154 including dummy bond pads may be located only where other devices are to be attached.

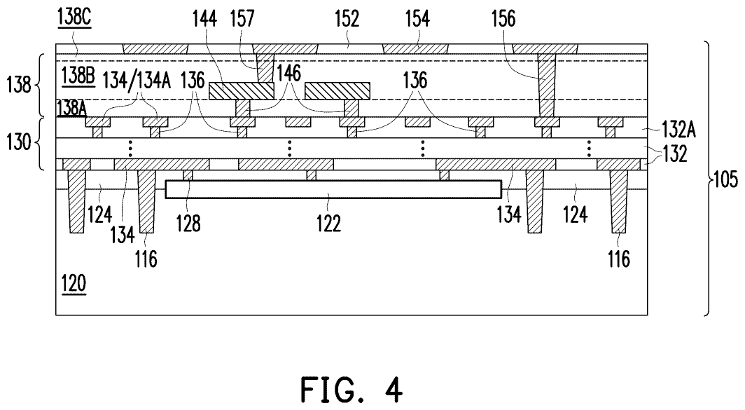

FIG. 4 illustrates the device die 105 after being singulated from the wafer 100. The singulation process 160 (see FIG. 3) used to singulate the device die from the wafer 100 may be any suitable process, such as using a die saw, a laser cutting, or the like to cut through the wafer 100 and structures formed thereupon.

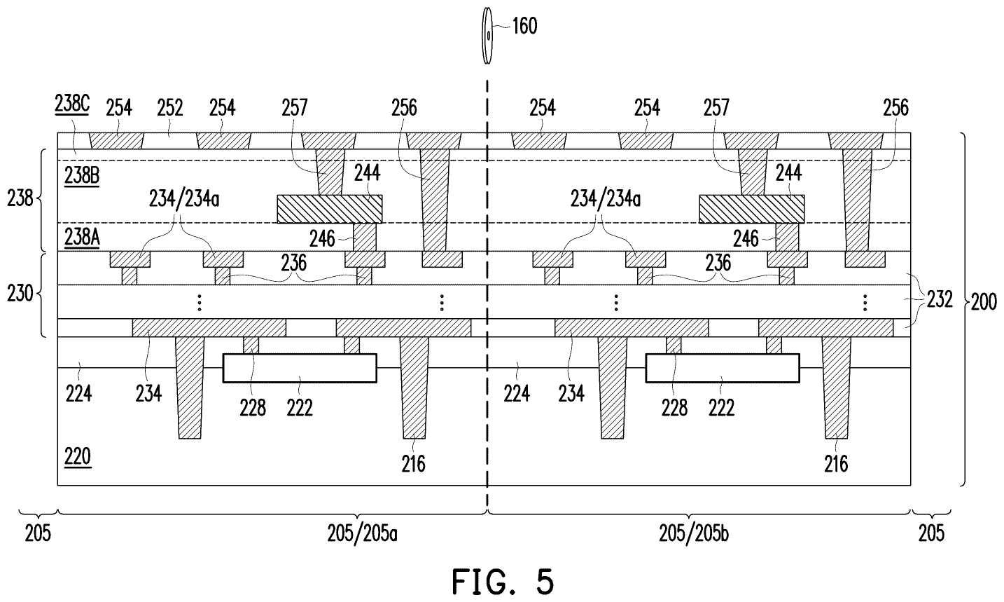

FIG. 5 illustrates the formation of wafer 200, which includes device dies 205 (e.g., device die 205a and device die 205b) therein. In accordance with some embodiments of the present disclosure, device dies 205 are logic dies, which may be CPU dies, MCU dies, IO dies, Base-Band dies, or AP dies. Device dies 205 may also be memory dies. Wafer 200 includes semiconductor substrate 220, which may be a silicon substrate.

Device dies 205 may include integrated circuit devices 222, ILD 224 over the integrated circuit devices 222, and contact plugs 228 to electrically connect to the integrated circuit devices 222. Device dies 205 may also include interconnect structures 230 for connecting to the active devices and passive devices in device dies 205. Interconnect structures 230 include metal lines 234 and vias 236.

Through-Silicon Vias (TSVs) 216, sometimes referred to as through-semiconductor vias or through-vias, may optionally be formed to penetrate into the semiconductor substrate 220 (and eventually through the semiconductor substrate 220 by revealing from the opposite side). If utilized, the TSVs 216 may be used to connect the devices and metal lines formed on the front side (the illustrated top side) of semiconductor substrate 220 to the backside. TSVs 216 may be formed using processes and materials similar to those used to form the bond pad vias 156, discussed above, and are not repeated, including for example a time-based etching process so that the TSVs 216 may have a bottom which is disposed between the top surface and the bottom surface of the semiconductor substrate 220.

Device die 205 may include dielectric layers 238 and dielectric bonding layer 252. Vias 246 and metal features 244 may be formed and disposed in the dielectric layers 238 (which may include multiple dielectric layers 238A, 238B, and 238C). Bond pad vias 256 and bond pad vias 257 are also formed and disposed in dielectric layers 238, and bond pads 254 are formed and disposed in the dielectric bonding layer 252.

The processes and materials used to form the various features of device die 205 may be similar to the process and materials used to form their like features in device die 105, and hence the details are not repeated herein. Like features between device die 105 and device die 205 share the same last two numbers in their labels.

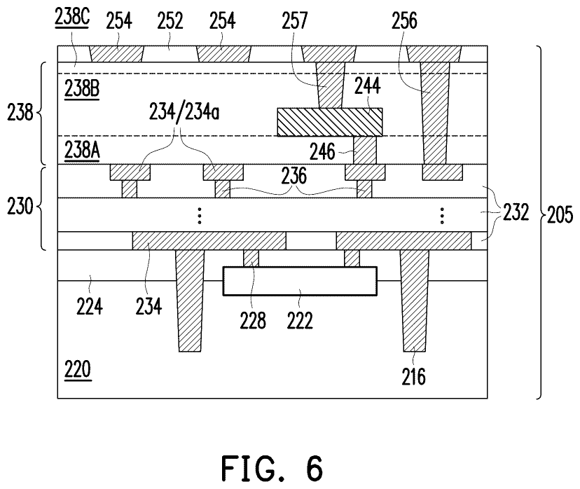

In FIG. 6, wafer 200 is singulated into a plurality of discrete device dies 205, including for example, device die 205a and device die 205b. The singulation process 160 (see FIG. 5) may be the same or similar to the singulation process discussed above with respect to FIG. 4.

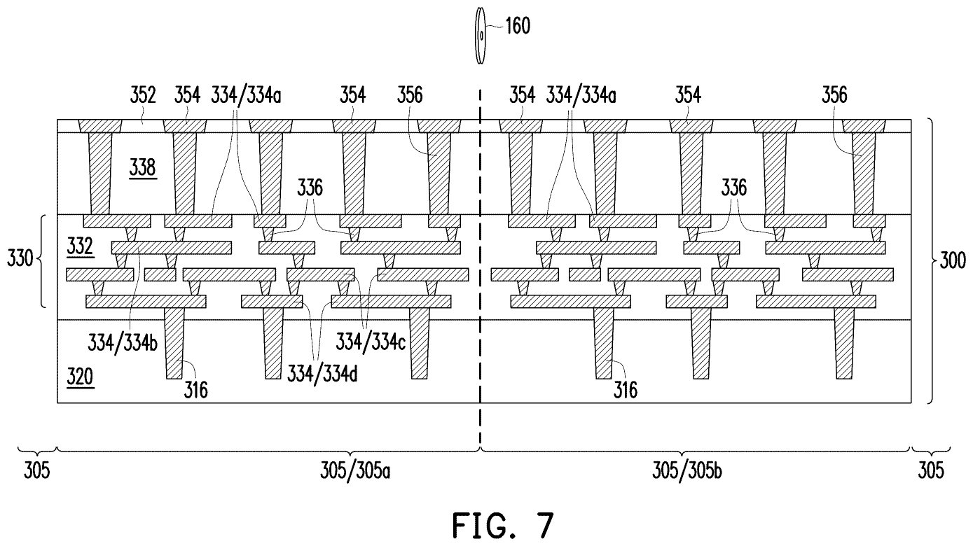

FIG. 7 illustrates the formation of wafer 300, which includes bridge dies 305 (e.g., silicon bridge dies 305a and 305b) therein, in accordance with some embodiments. The substrate 320 may include any of the candidate substrates discussed above with respect to the semiconductor substrate 120. An interconnect structure 330 is provided to electrically connect the various bond pads 354 to others of the various bond pads 354 and/or to the optional TSVs 316.

The interconnect structure 330 includes dielectric layers 332, and metal lines 334 and vias 336 formed in dielectric layers 332. Forming the interconnect structure 330 may use the same processes and materials as those described above with respect to the interconnect structure 130 (and dielectric layers 132 for the dielectric layers 332, metal lines 134 for the metal lines 334, and vias 136 for the vias 336).

Optional TSVs 316 are also illustrated in FIG. 7. The TSVs 316 may be formed prior or at the same time as forming the bottom metal lines 334d. The TSVs 316 penetrate into the substrate 320 (and may optionally be revealed from the opposite side in a subsequent process). If utilized, the TSVs 316 may be used to connect the devices and metal lines formed on the front side (the illustrated top side) of substrate 320 to the backside. TSVs 316 may be formed using processes and materials similar to those used to form the bond pad vias 156, discussed above, and are not repeated, including for example a time-based etching process so that the TSVs 316 may have a bottom which is disposed between the top surface and the bottom surface of the substrate 320.

Bridge dies 305 may include dielectric layers 338 and a dielectric bonding layer 352. Bond pad vias 356 are formed and disposed in dielectric layers 338, and bond pads 354 are formed and disposed in the dielectric bonding layer 352. The processes and materials used to form the various features of the bridge dies 305 may be similar to the processes and materials used to form their like features in device die 105, and hence the details are not repeated herein. Like features between device die 105 and bridge die 305 share the same last two numbers in their labels.

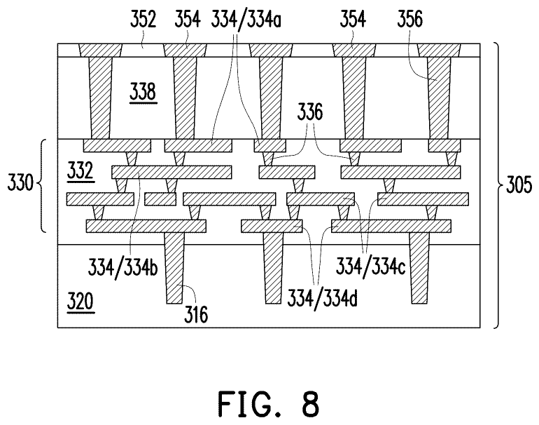

In FIG. 8, wafer 300 is singulated into a plurality of discrete bridge dies 305, including for example, silicon bridge die 305a and silicon bridge die 305b. The singulation process 160 (see FIG. 7) may be the same or similar to the singulation process discussed above with respect to FIG. 4.

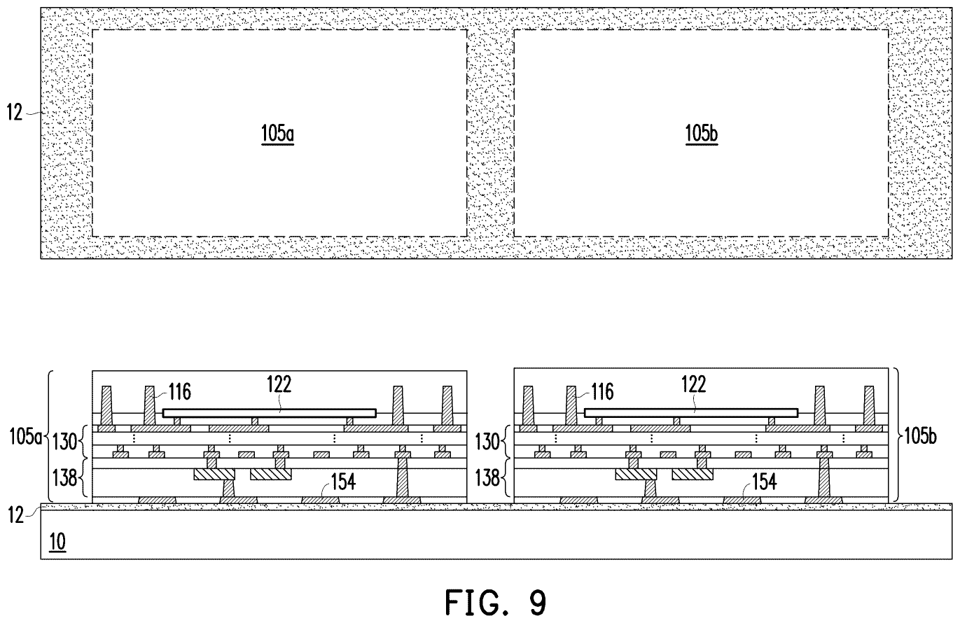

FIGS. 9 through 20 illustrate intermediate steps in the formation of a SOIC package utilizing a silicon bridge die (such as the bridge die 305). Although the processes are described in relation to the utilization of the bridge die 305, the bridge die 405, 505, or 605, may be substituted. FIGS. 9 through 16 illustrate top views according to some example embodiments at the top of each of the figures and cross-sectional views at the bottom of each of the figures. It should be understood that these views are merely examples and variations are within the scope of this description. For example, the top view and cross-sectional view provided for each of the Figures may only be partial views and other devices or structures may be incorporated.

In FIG. 9, a carrier substrate 10 is provided and a release layer 12 is formed on the carrier substrate 10. The carrier substrate 10 may be a glass carrier substrate, a ceramic carrier substrate, or the like. The carrier substrate 10 may be a wafer, such that multiple packages can be formed on the carrier substrate 10 simultaneously.

The release layer 12 may be formed of a polymer-based material, which may be removed along with the carrier substrate 10 from the overlying structures that will be formed in subsequent steps. In some embodiments, the release layer 12 is an epoxy-based thermal-release material, which loses its adhesive property when heated, such as a light-to-heat-conversion (LTHC) release coating. In other embodiments, the release layer 12 may be an ultra-violet (UV) glue, which loses its adhesive property when exposed to UV lights. The release layer 12 may be dispensed as a liquid and cured, may be a laminate film laminated onto the carrier substrate 10, or may be the like. The top surface of the release layer 12 may be leveled and may have a high degree of planarity.

Two or more of the device dies 105 may be placed on the carrier substrate 10 and attached to the release layer 12. Each of the device dies 105, such as device die 105a and 105b, may be placed on the carrier substrate 10 by a pick and place process to place the device dies 105 face down (back side up). It should be understood that each of the device dies 105 may have the same or different functionalities, and may be the same size as each other or different sizes from each other.

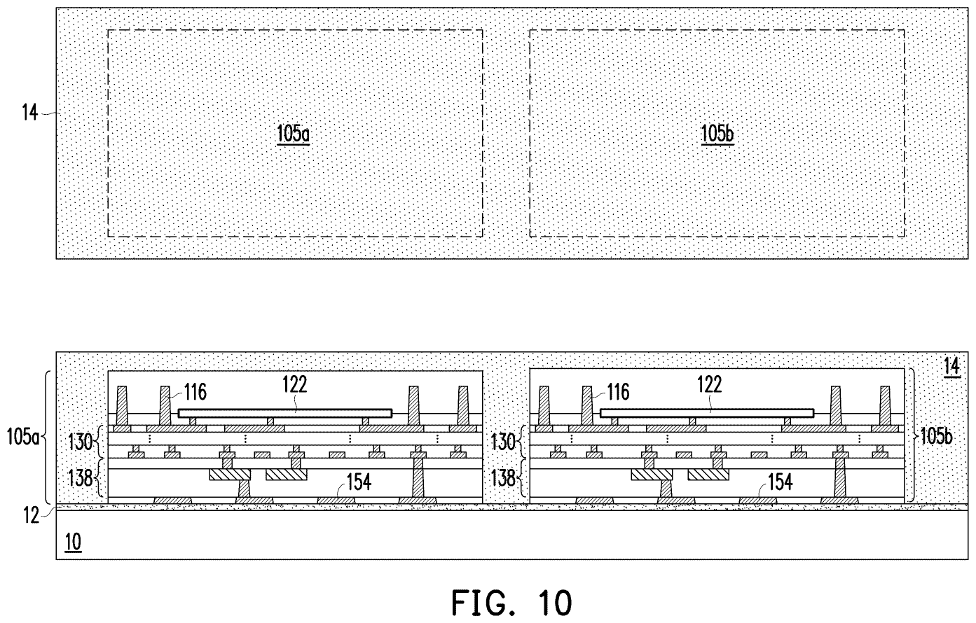

In FIG. 10, a fill material, such as an insulating material or encapsulant 14 may be deposited over and laterally surrounding the device dies 105. The encapsulant 14 may include a dielectric material such as a resin, epoxy, polymer, oxide, nitride, the like, or combinations thereof, which may be deposited by any suitable process, such as by flowable CVD, spin-on, PVD, the like, or combinations thereof.

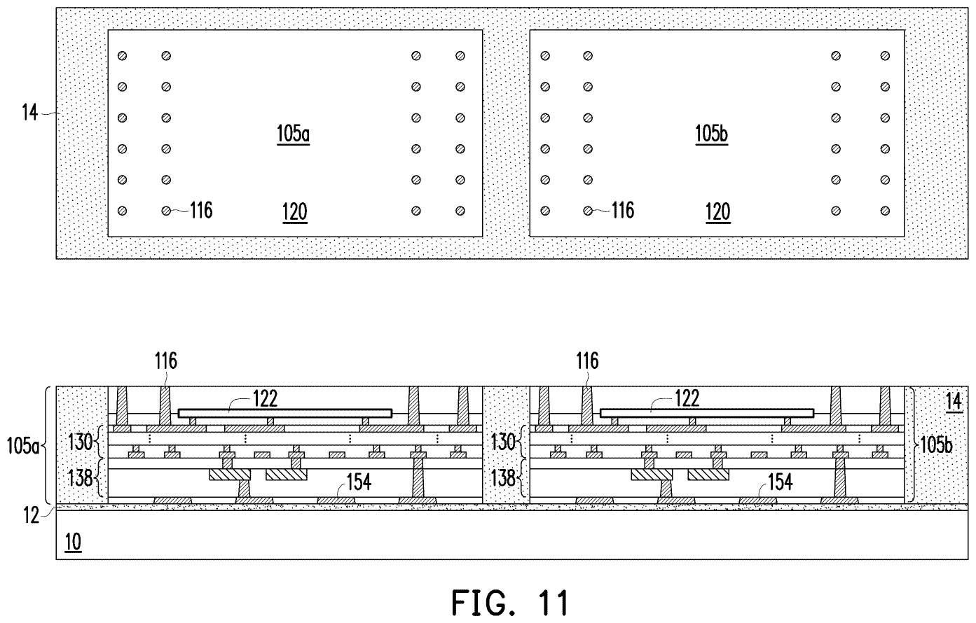

In FIG. 11, a planarization process may be used to level the upper surface of the encapsulant 14 with the upper surfaces of the device dies 105. The planarization process may include a grinding and/or a chemical mechanical polishing (CMP) processes. The planarization process may be continued until the TSVs 116 are exposed through the semiconductor substrates 120 (see FIG. 4) of the device dies 105.

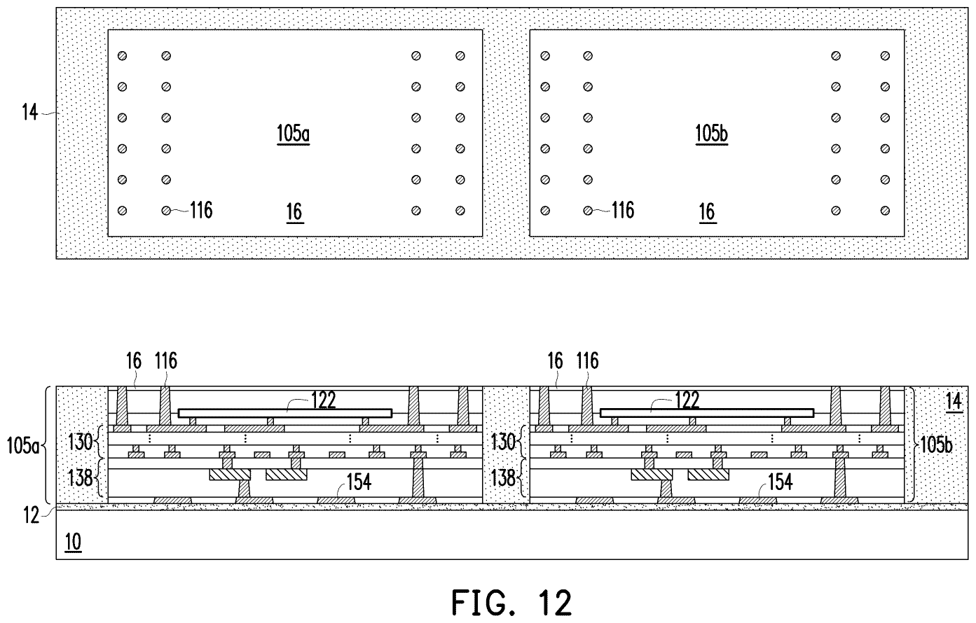

In FIG. 12, the semiconductor substrate 120 (see FIG. 4) of each of the device dies 105 may be recessed to further expose the TSVs 116, causing them to protrude from the upper surface of the semiconductor substrate 120. In embodiments which do not utilize TSVs 116, TSVs may be formed by etching openings through the semiconductor substrate 120 to the interconnect structure 130 and forming the TSVs (e.g., using processes and materials described above with respect to the TSVs 116). After recessing the semiconductor substrate 120, an insulating layer 16 may be formed by depositing an insulating material over the upper surfaces (i.e., the back sides) of the device dies 105 and planarizing the insulating material to level the upper surfaces of the insulating material with the upper surfaces of the encapsulant 14, thereby forming the insulating layer 16 over each of the device dies 105.

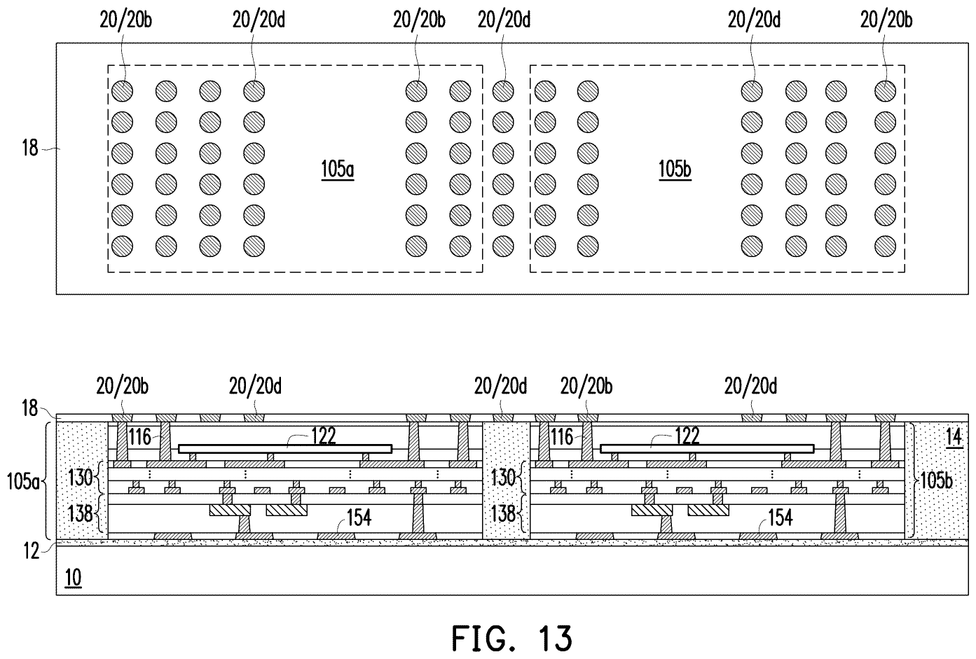

In FIG. 13, a bonding layer 18 may be formed over the upper surface of the encapsulant 14 and the insulating layers 16. Bond pads 20 are formed in the bonding layer 18. The bond pads 20 may include active bond pads 20b which are physically coupled to a TSV 116 and dummy bond pads 20d which are not connected to any metal features of the device dies 105. The bonding layer 18 may be formed of any suitable insulating layer, such as silicon oxide, silicon nitride, silicon carbide, silicon oxycarbide, silicon oxynitride, the like, or combinations thereof, and may be deposited using any suitable technique, such as CVD, PVD, spin on, etc. To form the bond pads 20, openings may be formed in the bonding layer 18 according to the positions of the bond pads 20. The openings may be formed using photo resists (not shown) and/or hard masks (not shown) which are formed and patterned over the bonding layer 18 to aid the formation of the openings for the bond pads 20. In some embodiments, an anisotropic etch or wet etch is performed to form the openings for the bond pads 20. The etch may stop on the encapsulant 14 and insulating layers 16. The openings for the bond pads 20 may expose upper surfaces of the TSVs 116.

Next, a diffusion barrier and metallic material may be deposited in the openings to form the bond pads 20. The diffusion barrier and metallic material may be deposited using materials and techniques such as those discussed above for the formation of the bond pad vias 156 and 157. A planarization process such as a Chemical Mechanical Polish (CMP) process may then be performed to remove excess portions of the metallic material and the diffusion barrier, until the bonding layer 18 is exposed. The remaining portions of the diffusion barrier and metallic material include bond pads 20 which are subsequently used for bonding to another device.

As illustrated in FIG. 13, in some embodiments, one or more dummy bond pads 20d may be disposed over a portion of the encapsulant 14 which is between the two device dies 105. The dummy bond pads 20d may be included for pattern loading considerations and may also help provide a better direct bonding, which less likelihood of failure.

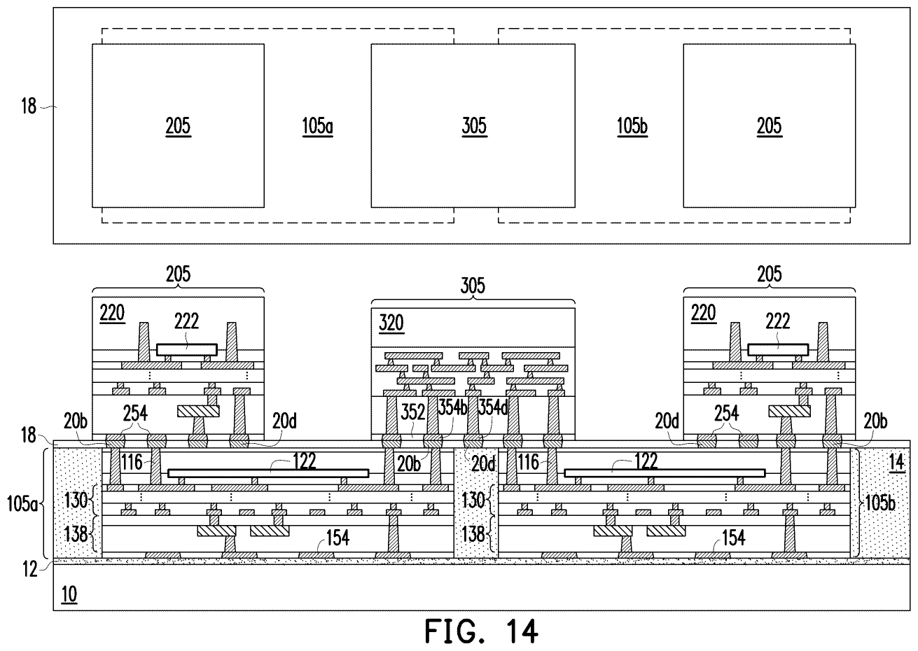

In FIG. 14, the bridge die 305 is bonded simultaneously to at least two of the device dies 105. In addition, as illustrated in FIG. 14, one or more secondary device dies 205 may also optionally be bonded to the device dies 105. Each of the pieces may be positioned over the bond pads 20 using a pick and place process. In some embodiments, each device die 205 and each bridge die 305 may be placed and bonded one at a time, while in other embodiments, all of the device dies 205 and bridge dies 305 may be placed and then all bonded together at the same time. The bonding mechanism for bonding the bridge die 305 to the device dies 105a and 105b may utilize a hybrid bonding process, where the metal of the bond pads 20 are directly bonded to the metal of the bond pads 354 (see FIG. 8) and to the metal of the bond pads 254 (see FIG. 6), without the use of solder material at an interface of the bond pads 354 and the bond pads 254.

Each of the device dies 205 bonded to the device dies 105 may have been tested and determined to be a KGD prior to bonding to the device dies 105. While one device die 205 is illustrated as being bonded to each of the device dies 105a and 105b, it should be appreciated that other device dies like unto the device die 205 may be bonded to the device dies 105. The other device dies may be identical to the device die 205 or may be different from the device die 205. For example, the device dies 205 and other device dies may be different types of dies selected from the above-listed types. Also, device dies 205 may be a digital circuit die, while the other device dies may be an analog circuit die. Device dies 105 and 205 (and other device dies, if any) in combination function as a system. Splitting the functions and circuits of a system into different dies such as device dies 105 and 205 may optimize the formation of these dies, and may result in the reduction of manufacturing cost.

The bonding of device dies 205 and bridge dies 305 to device dies 105a and 105b may be achieved through hybrid bonding. For example, bond pads 254 and 354 are bonded to bond pads 20 through metal-to-metal direct bonding. In accordance with some embodiments of the present disclosure, the metal-to-metal direct bonding is copper-to-copper direct bonding. Bond pads 254 and 354 may have sizes greater than, equal to, or smaller than, the sizes of the respective bond pads 20. Furthermore, dielectric bonding layers 252 and 352 are bonded to bonding layer 18 through dielectric-to-dielectric bonding, which may be fusion bonding, for example, with Si—O—Si bonds generated.

To achieve the hybrid bonding, device dies 205 and the bridge dies 305 are positioned in relation to the devices dies 105 to align their respective bond pads 20 (i.e., 20b and 20d) and bond pads 254 of the device dies 205 and bond pads 354 of the bridge dies 305. The upper dies (device dies 205 and bridge die 305) are pressed together with the lower device dies 105a and 105b. Then, an anneal is performed to cause the inter-diffusion of the metals in bond pads 20 and the corresponding overlying bond pads 254 and 354. The annealing temperature may be higher than about 350° C., and may be in the range between about 3500 and about 550° C. in accordance with some embodiments. The annealing time may be in the range between about 1.5 hours and about 3.0 hours, and may be in the range between about 1.0 hour and about 2.5 hours in accordance with some embodiments. Through the hybrid bonding, bond pads 254 and bond pads 354 are bonded to the corresponding bond pads 20 through direct metal bonding caused by metal inter-diffusion. Likewise, the dielectric bonding layer 252 and dielectric bonding layer 352 are fusion bonded to the corresponding bonding layer 18.

As seen in FIG. 14, the dummy bond pad 20d disposed over the encapsulant 14 between the device dies 105a and 105b may be coupled to a corresponding bond pad 354 of the bridge die 305.

Utilizing hybrid bonding to attach the bridge die 305, the device die 105a may be cross connected to the device die 105b while reducing energy consumption, providing less contact resistance, and providing higher frequency through-put than bridge devices which are attached using bump connectors.

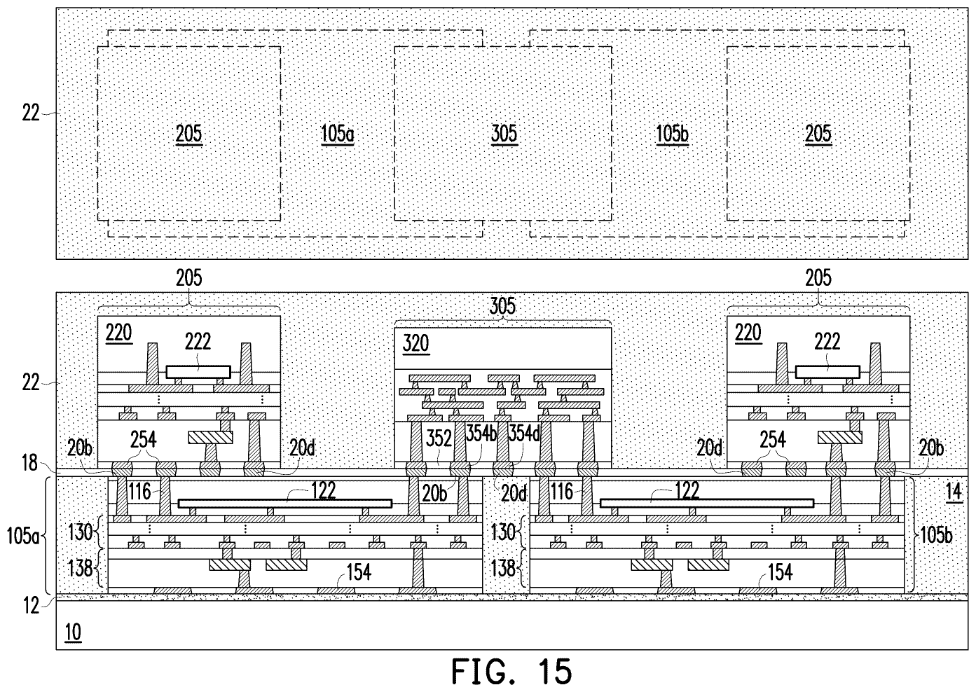

In FIG. 15, a fill material, such as an insulating material or encapsulant 22 may be deposited over and laterally surrounding the device dies 105. The encapsulant 22 may include a dielectric material such as a resin, epoxy, polymer, oxide, nitride, the like, or combinations thereof, which may be deposited by any suitable process, such as by flowable CVD, spin-on, PVD, the like, or combinations thereof.

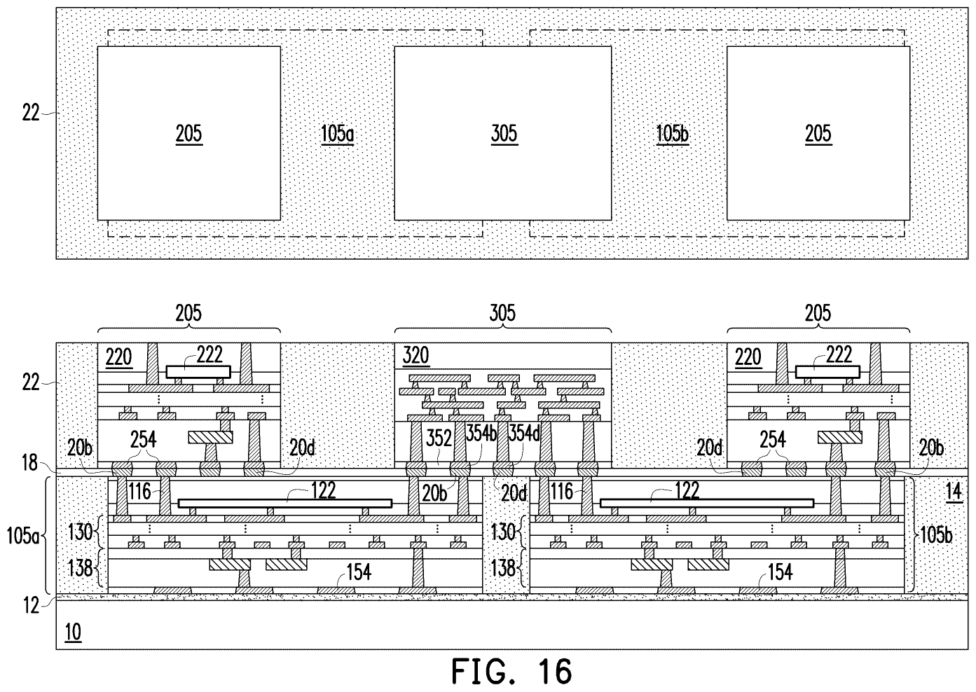

In FIG. 16, a planarization process may be used to level the upper surface of the encapsulant 22 with the upper surfaces of the device dies 205 and upper surfaces of the bridge die 305. The planarization process may include a grinding and/or a chemical mechanical polishing (CMP) processes. The planarization process may be continued until the TSVs 216 (if used) (see FIG. 6) are exposed through the substrate 220 of the device dies 205 and until the TSVs 316 (if used) (see FIG. 8) are exposed through the substrate 320 of the bridge die 305.

In some embodiments, the structure of FIG. 16 is merely one package site in a plurality of package sites. For example, the carrier substrate 10 may be a wafer extending beyond the illustrated sidewalls of the encapsulant 14 and additional package areas may be formed adjacent to the illustrated package area. Such package areas may be singulated from one another in a subsequent process. In such embodiments, the encapsulant 14, bonding layer 18, and encapsulant 22 may also extend to the lateral extents of the carrier substrate 10. In other embodiments, the structure illustrated in FIG. 16 is a distinct structure and may be individually formed on individual carrier substrates 10.

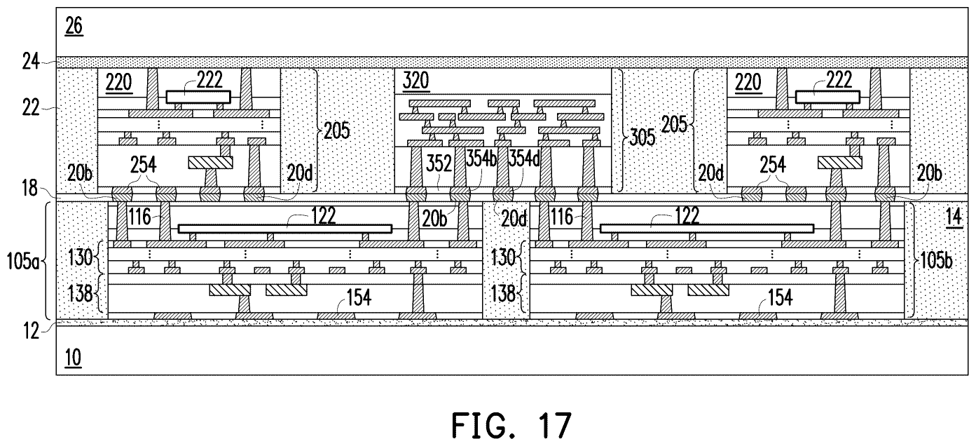

In FIG. 17, a wafer bonding layer 24 may be deposited over the structure of FIG. 16 and a wafer 26 may be bonded to the structure of FIG. 16. In some embodiments, the wafer 26 may be a support wafer and may be made of any suitable material, such as silicon, sapphire, or the like. The wafer bonding layer 24 may be deposited using a spin-on technique to achieve a high degree of planarity and the wafer may be pressed against the wafer bonding layer 24 for adhesion thereto. The wafer bonding layer may include any suitable material, such as, silicon oxynitride, silicon carbo-nitride, undoped silicon glass, a TEOS formed silicon oxide, the like, or combinations thereof, deposited by CVD, PECVD, HDP-CVD (high density plasma CVD), and so forth. In some embodiments, the wafer bonding layer may include gold, indium, tin, copper, the like, or combinations thereof, deposited by sputtering, PVD, plating (electro or electroless), and so forth. In yet other embodiments, the wafer bonding layer may include a polymer or glue and may be deposited by spin-on, lamination, and so forth.

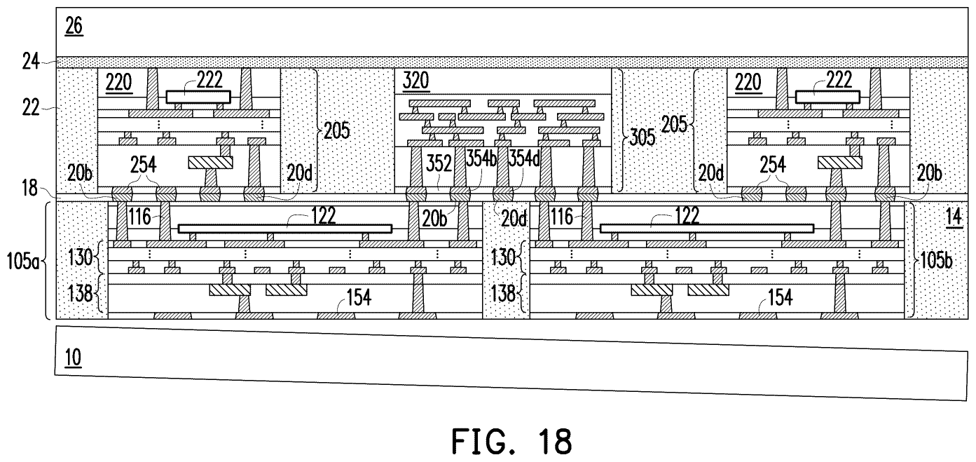

In FIG. 18, a carrier substrate de-bonding is performed to detach (or “de-bond”) the carrier substrate 10 from the front side of the device dies 105 and encapsulant 14. In accordance with some embodiments, the de-bonding includes projecting a light such as a laser light or an UV light on the release layer 12 so that the release layer 12 decomposes under the heat of the light and the carrier substrate 10 can be removed. The structure may then flipped over and placed on a tape (not shown).

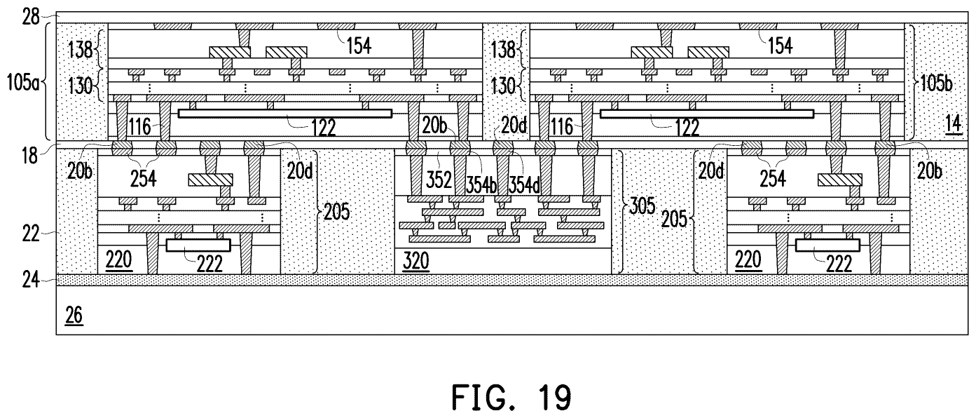

In FIG. 19, a passivation layer 28 is formed over the front side of the device dies 105a and 105b and the encapsulant 14. The passivation layer 28 may be a single layer or a composite layer, and may be formed of a non-porous material. In some embodiments, the passivation layer 28 is a composite layer including a silicon oxide layer (not shown separately), and a silicon nitride layer (not shown separately) over the silicon oxide layer. The passivation layer 28 may also be formed of other non-porous dielectric materials such as undoped Silicate Glass (USG), silicon oxynitride, and/or the like. The passivation layer 28 may also be formed of polyimide, polybenzoxazole (PBO), or the like. The passivation layer 28 may be deposited by any suitable technique, such as by PVD, CVD, spin-on, the like, or combinations thereof.

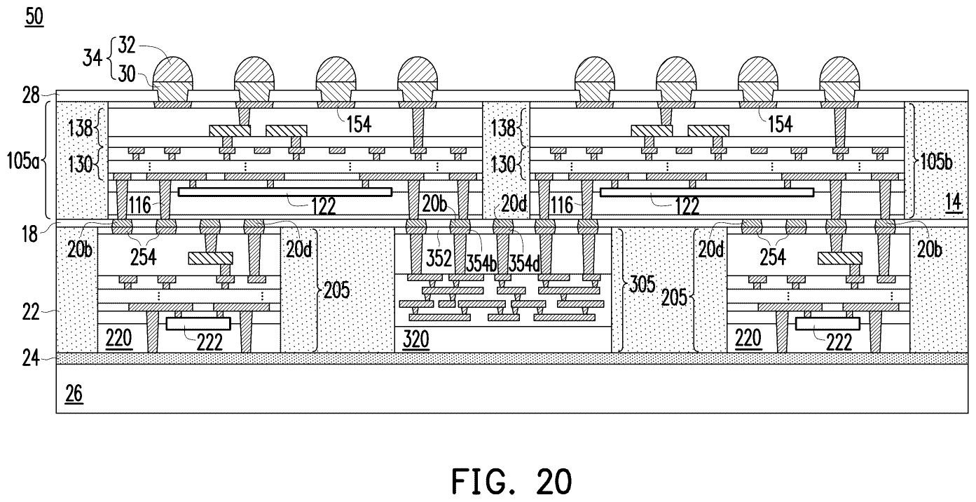

In FIG. 20, the passivation layer 28 is patterned, so that openings in the passivation layer 28 expose the bond pads 154 of the device dies 105a and 105b. Contacts 34 may be formed in the openings and electrically and physically coupled to the bond pads 154 of the device dies 105a and 105b. In some embodiments, the contacts 34 may include an underbump metallization 30 and solder bump 32. In other embodiments, the solder bump 32 may be formed directly on the bond pads 154.

The resulting package structure 50 may be further utilized in a flip chip package, a chip on wafer on substrate package, or an integrated fan out package.

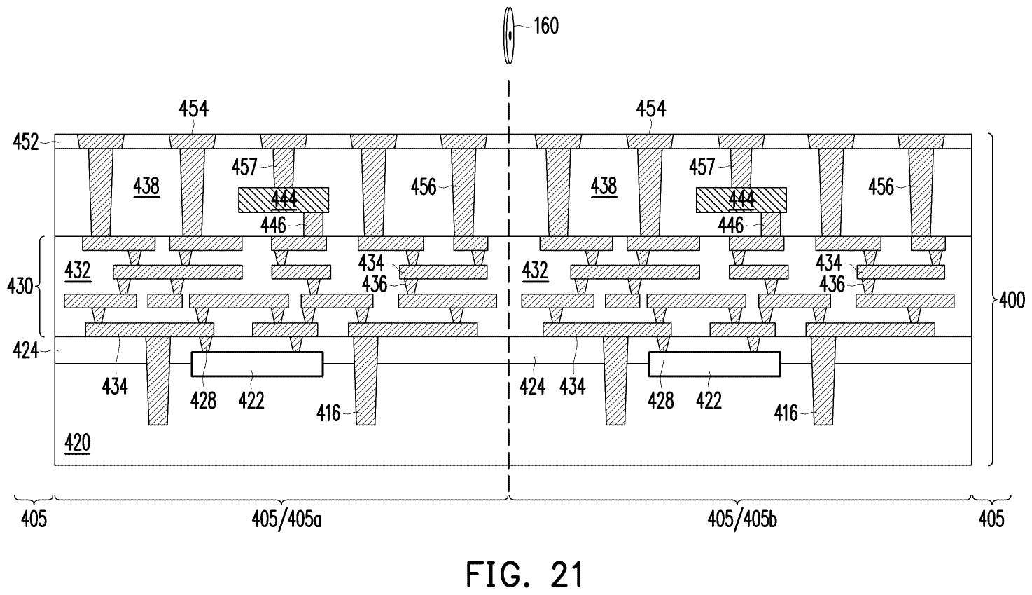

FIGS. 21 through 23 illustrate the formation of a package structure 50 including a bridge die 405, where the bridge die 405 includes an integrated passive device (IPD). FIG. 21 illustrates the formation of wafer 400, which includes bridge dies 405 (e.g., bridge die 405a and 405b). The bridge dies 405 have a first purpose of forming a bridge between bond pads 454 at one side of the die (i.e., to couple to a first device die) and bond pads 454 at another side of the die (i.e., to couple to a second device die). The bridge dies 405 also have a second purpose of including one or more IPDs 422, such as a capacitor, a resistor, an inductor, a diode, a transformer, a thermistor, a varactor, a transducer, etc. In some embodiments, the IPDs 422 may be utilized along a circuit path from one or more of the bond pads 454 at one side of the bridge die 405 to one or more of the bond pads 454 at the other side of the bridge die 405. In some embodiments, IPDs 422 may be utilized along a circuit path from one or more of the bond pads 454 at one side of the bridge die 405 to one or more bond pads 454 on the same side of the bridge die 405.

The bridge dies 405 may include optional TSVs 416 which are electrically coupled to the interconnect structure 430. The bridge dies 405 may also include metal features 444 which may be used for testing that the functionality of the bridge die 405 is as intended, to determine whether the bridge dies 405 are known good dies (KGDs). The processes and materials used to form the various features of bridge die 405 may be similar to the process and materials used to form their like features in device die 105, and hence the details are not repeated herein. Like features between device die 105 and the bridge die 405 share the same last two numbers in their labels.

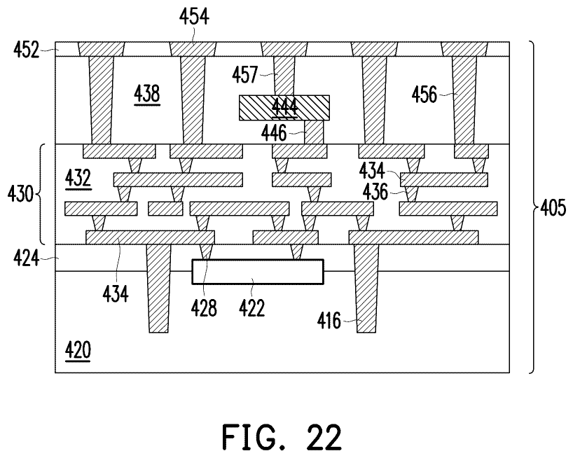

In FIG. 22, wafer 400 is singulated into a plurality of discrete bridge dies 405, including for example, bridge die 405a and bridge die 405b. The singulation process 160 (see FIG. 21) may be the same or similar to the singulation process discussed above with respect to FIG. 4.

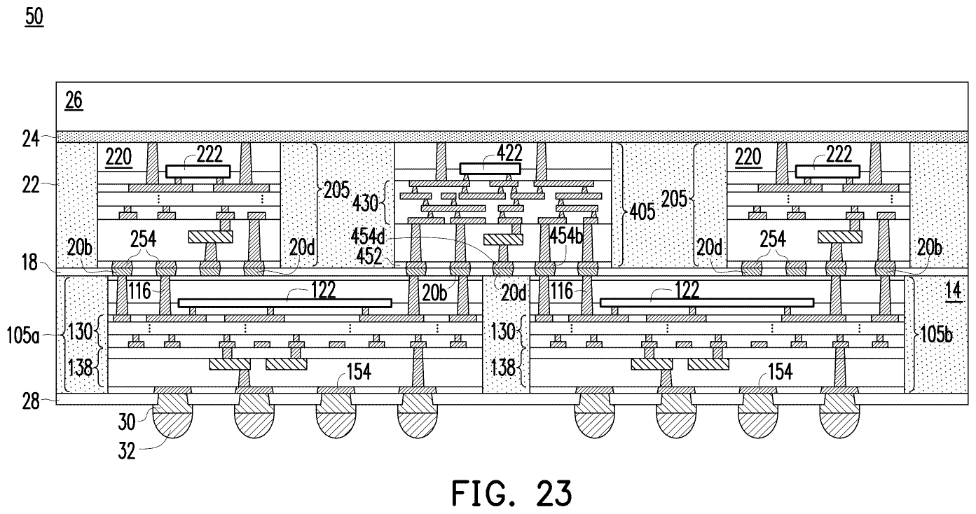

In FIG. 23, the package structure 50 is illustrated which utilizes the bridge die 405 in place of the bridge die 305 (see FIGS. 9 through 20).

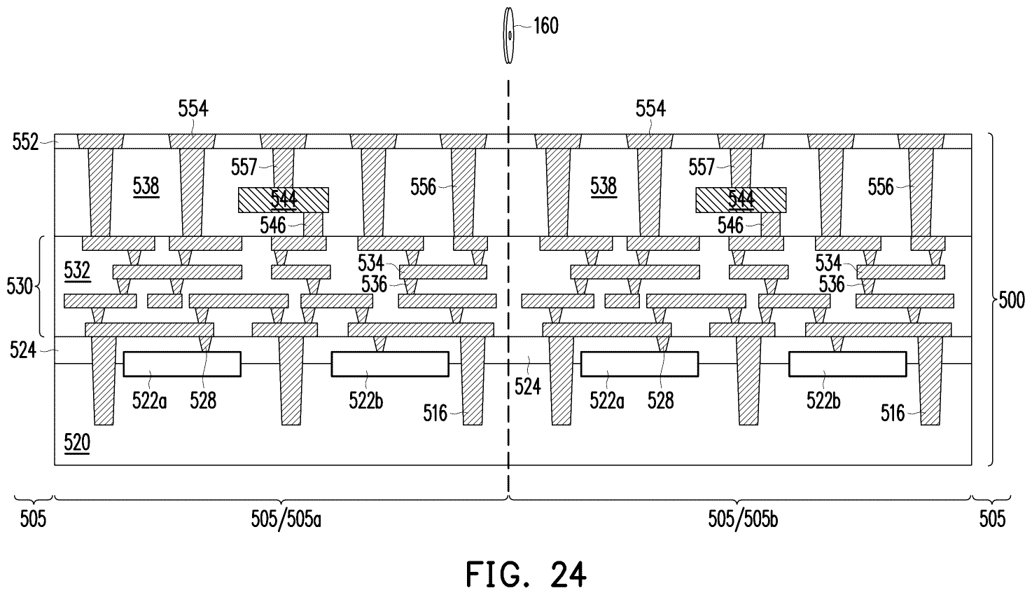

FIGS. 24 through 26 illustrate the formation of a package structure 50 including a bridge die 505, where the bridge die 505 includes an active device. FIG. 24 illustrates the formation of wafer 500, which includes bridge dies 505 (e.g., bridge die 505a and 505b). The bridge dies 505 have a first purpose of forming a bridge between bond pads 554 at one side of the die (i.e., to couple to a first device die) and bond pads 554 at another side of the die (i.e., to couple to a second device die). The bridge dies 505 also have a second purpose of including one or more active devices 522, such as transistors. In some embodiments, the active devices 522 may be utilized along a circuit path from one or more of the bond pads 554 at one side of the bridge die 505 to one or more of the bond pads 554 at the other side of the bridge die 505. In some embodiments, active devices 522 may be utilized along a circuit path from one or more of the bond pads 554 at one side of the bridge die 505 to one or more bond pads 554 on the same side of the bridge die 505.

The bridge dies 505 may include optional TSVs 516 which are electrically coupled to the interconnect structure 530. The bridge dies 505 may also include metal features 544 which may be used for testing that the functionality of the bridge die 505 is as intended, to determine whether the bridge dies 505 are known good dies (KGDs). The processes and materials used to form the various features of bridge die 505 may be similar to the process and materials used to form their like features in device die 505, and hence the details are not repeated herein. Like features between device die 105 and the bridge die 505 share the same last two numbers in their labels.

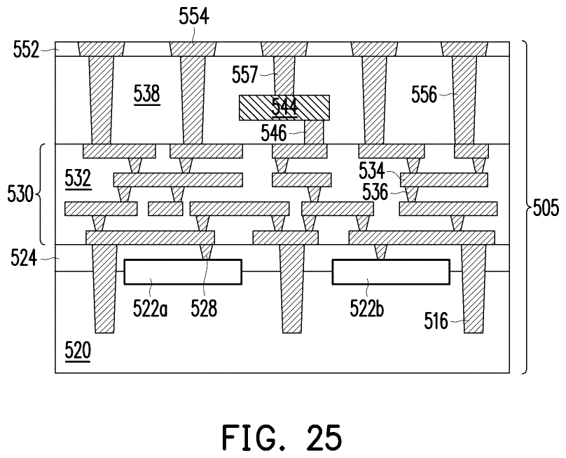

In FIG. 25, wafer 500 is singulated into a plurality of discrete bridge dies 505, including for example, bridge die 505a and bridge die 505b. The singulation process 160 (see FIG. 24) may be the same or similar to the singulation process discussed above with respect to FIG. 4.

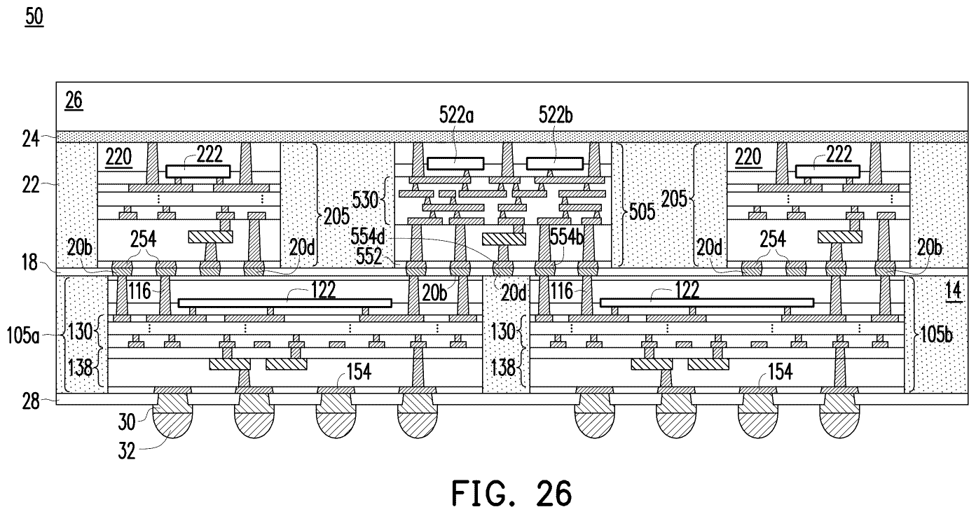

In FIG. 26, the package structure 50 is illustrated which utilizes the bridge die 505 in place of the bridge die 305 (see FIGS. 9 through 20).

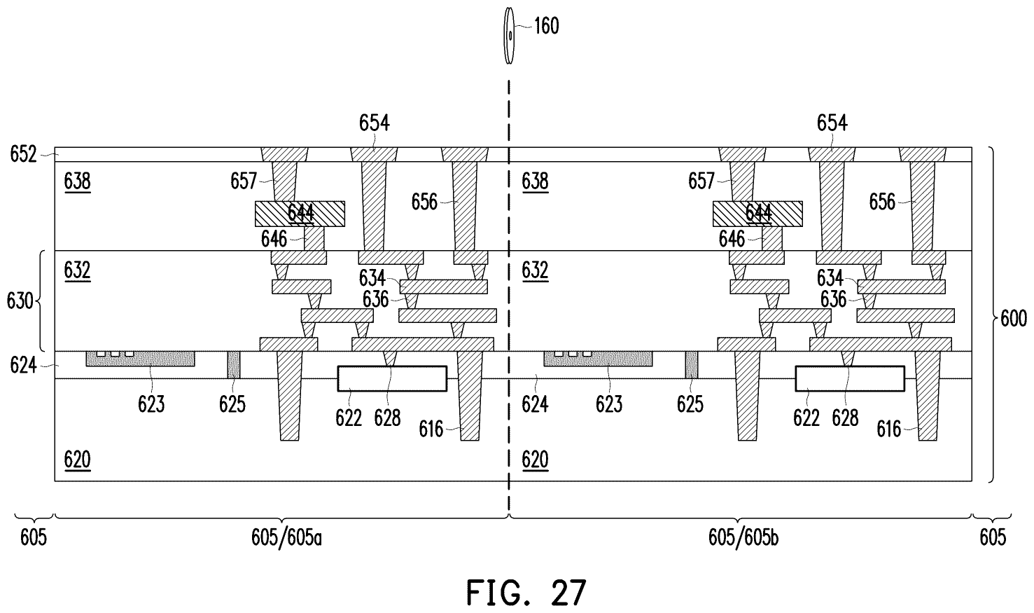

FIGS. 27 through 29 illustrate the formation of a package structure 50 including a bridge die 605, where the bridge die 605 includes a photonic element. FIG. 27 illustrates the formation of wafer 600, which includes bridge dies 605 (e.g., bridge die 605a and 605b). The bridge dies 605 have a first purpose of forming a bridge between bond pads 654 at one side of the die (i.e., to couple to a first device die) and bond pads 654 at another side of the die (i.e., to couple to a second device die). The bridge dies 605 also have a second purpose of including one or more photonic elements 623, such as light emitting diodes, laser diodes, solar and photovoltaic cells, displays, optical amplifiers, photo detectors, de-multiplexers, multiplexers, and attenuators, etc. In some embodiments, the photonic elements 623 may be utilized to affect signals in to or out of the bond pads 654 along a circuit path from one or more of the bond pads 654 at one side of the bridge die 605 to one or more of the bond pads 654 at the other side of the bridge die 605. In some embodiments, photonic elements 623 may be utilized along a circuit path from one or more of the bond pads 654 at one side of the bridge die 605 to one or more bond pads 654 on the same side of the bridge die 605. The bridge dies 605 may also have active or passive devices 622 optionally provided, for example, to assist in processing optical information from the photonic elements 623.

Metallic elements may be kept clear from the photonic elements 623. Accordingly, as illustrated in FIG. 27, metallic features may be formed apart from the photonic elements 623. An optional light barrier 625 may be deposited in the same layer as the photonic elements 623 to block light to and from sides of the bridge die 605.

The bridge dies 605 may include optional TSVs 616 which are electrically coupled to the interconnect structure 630. The bridge dies 605 may also include metal features 644 which may be used for testing that the functionality of the bridge die 605 is as intended, to determine whether the bridge dies 605 are known good dies (KGDs). The processes and materials used to form the various features of bridge die 605 may be similar to the process and materials used to form their like features in device die 605, and hence the details are not repeated herein. Like features between device die 105 and the bridge die 605 share the same last two numbers in their labels.

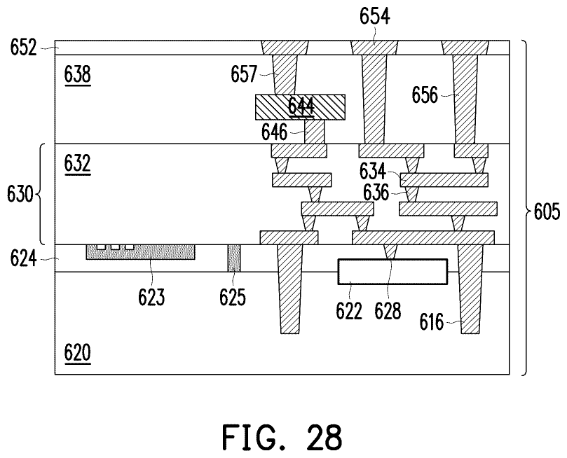

In FIG. 28, wafer 600 is singulated into a plurality of discrete bridge dies 605, including for example, bridge die 605a and bridge die 605b. The singulation process 160 (see FIG. 27) may be the same or similar to the singulation process discussed above with respect to FIG. 4.

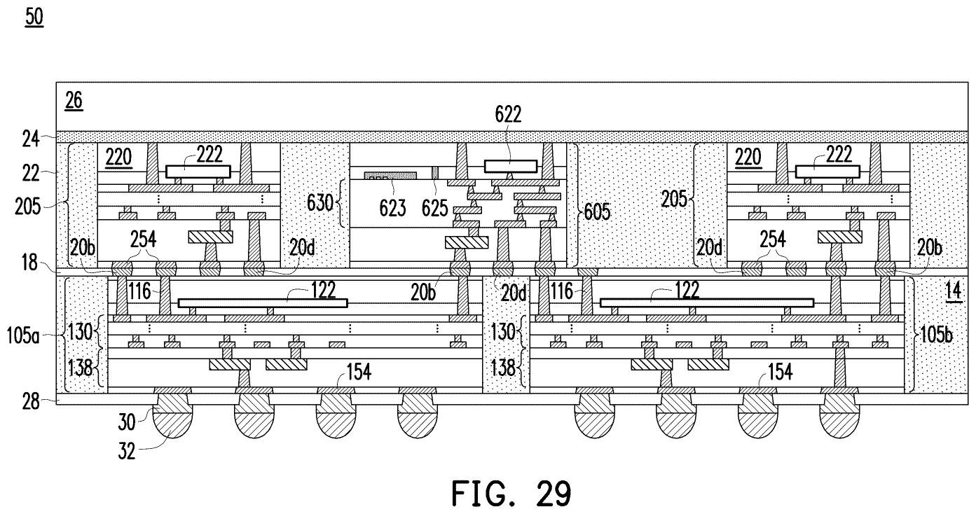

In FIG. 29, the package structure 50 is illustrated which utilizes the bridge die 605 in place of the bridge die 305 (see FIGS. 9 through 20).

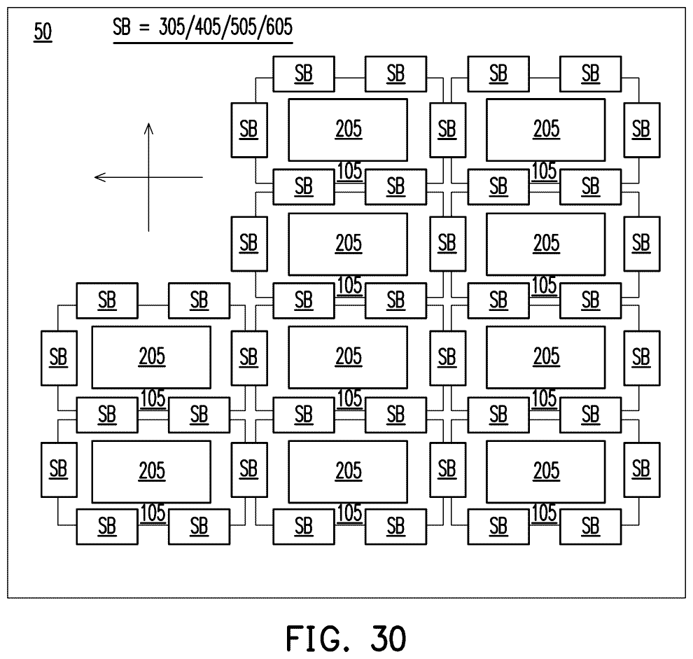

FIG. 30 is a top down view illustration of the use of multiple bridge dies SB (bridge dies 305/405/505/605) to bridge signals from multiple device dies 105. As indicated in FIG. 30, any number of bridge dies SB may be used and any number of device dies 105 may be used. In addition, multiple bridge dies SB may be used to connect two of the same device dies 105. Device dies 205 may be mounted over one or more of the device dies 105. Each of the multiple bridge dies SB that may be used may be of different types, such as described above.

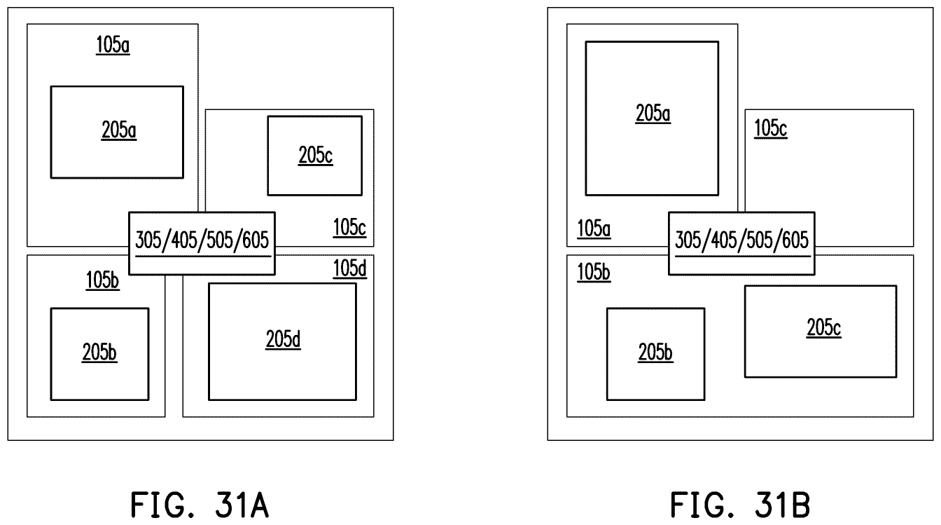

FIGS. 31A and 31B are top down view illustrations of the use of bridge dies across more than two device dies 105. FIG. 31B illustrates an embodiment that uses one bridge die to bridge three different underlying device dies 105, and FIG. 31A illustrates an embodiment that uses one bridge die to bridge four dies.

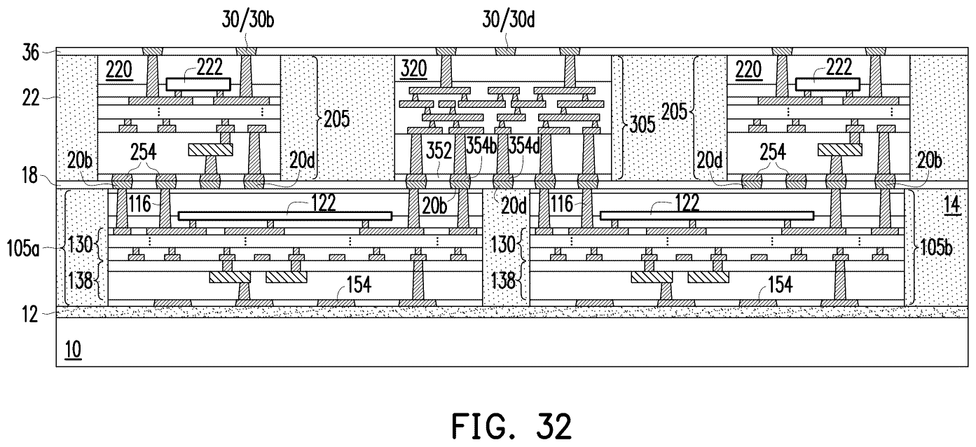

FIGS. 32 through 35 illustrate intermediate steps in the formation of a package structure 50, in accordance with some embodiments, which has two or more device dies added over top of the bridge die and connected to the bridge die to use the bridge die as a cross-connect between stacked device dies and/or laterally positioned device dies. The illustrated device in FIG. 32 represents a process applied to the device illustrated in FIG. 16.

In FIG. 32 a bonding layer 36 may be formed over the upper surface of the encapsulant 22. Bond pads 38 are formed in the bonding layer 36. The bond pads 38 may include active bond pads 38b which are physically coupled to a TSV 216 and dummy bond pads 38d which are not connected to any metal features of the bridge dies 305/405/505/605 or device dies 205. The materials and processes used to form the bonding layer 36 and bond pads 38 may be the same as those used to form the bonding layer 18 and bond pads 20, described above. An insulating layer (not separately shown) may be formed over the bridge dies 305/405/505/605 prior to forming the bonding layer 36. The insulating layer may be formed using processes and materials similar to those described above with respect to the insulating layer 16.

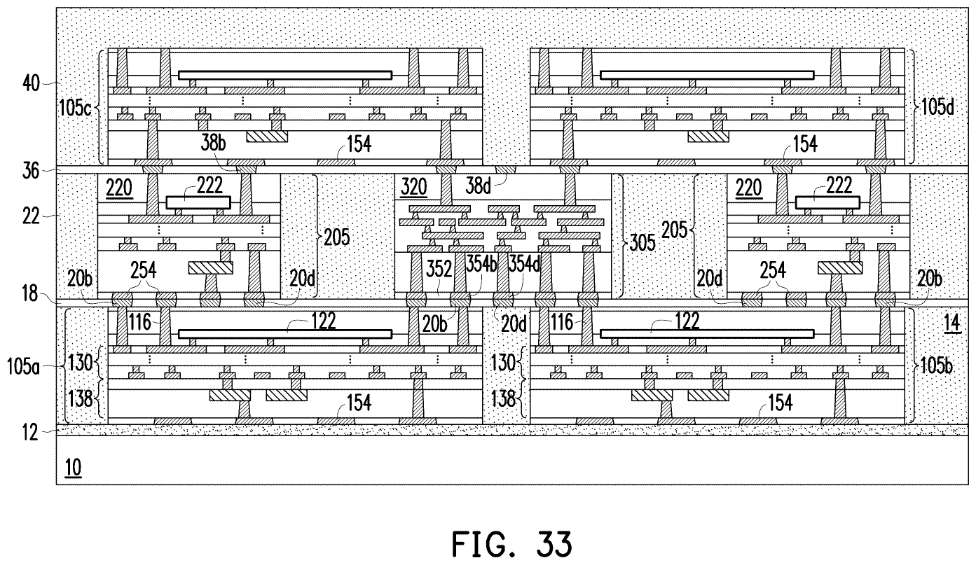

In FIG. 33, device dies 105c and 105d are bonded to the bond pads 38 and to the bonding layer 36. The device dies 105c and 105d may be bonded using a hybrid bonding technique, such as that described above with respect to FIG. 14. The device dies 105c and 105d may be bonded simultaneously to the bridge die 305/405/505/605 as well as the device die 205. An encapsulant 40 may be deposited over and laterally surrounding the device dies 105c and 105d, in a manner similar to the encapsulant 14, described above.

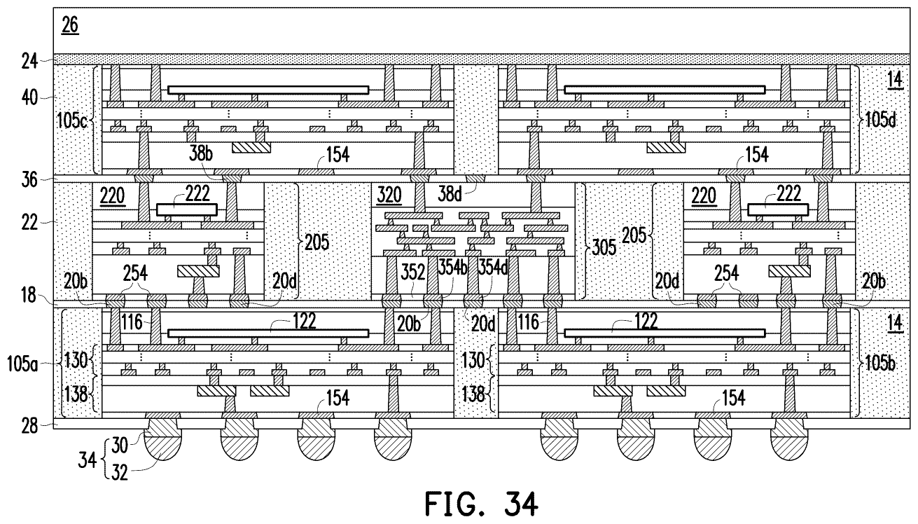

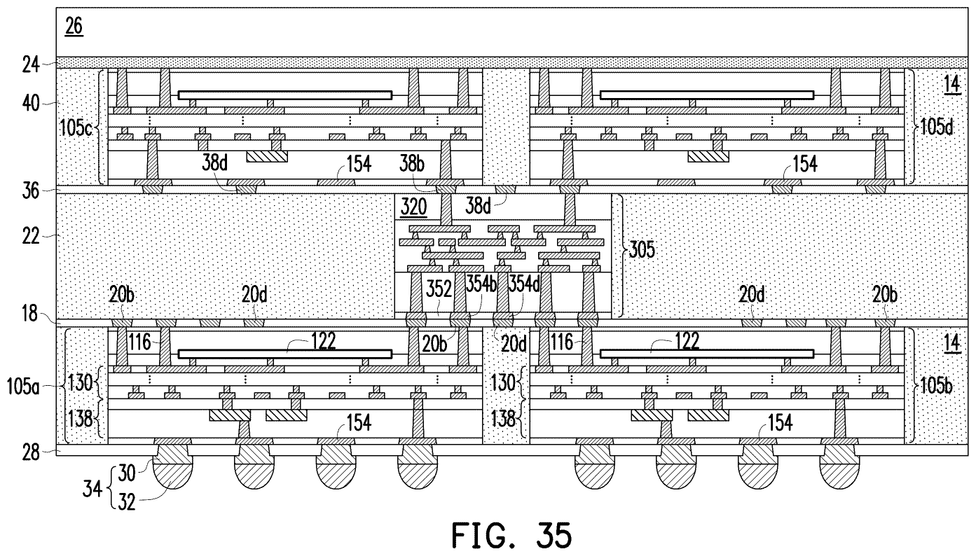

In FIG. 34, the processes described above with respect to FIGS. 17 through 20 are performed on the structure to form the package structure 50. In FIG. 35, the device dies 205 have been omitted from the package structure 50.

It should be understood and appreciated that each of the above-described embodiments may be combined with each other without limitation.

Embodiments provide advantages by utilizing hybrid bonding techniques in using a silicon bridge, high performance gains can be realized by reducing resistance, increasing high-frequency through-put, and decreasing power consumption and waste heat generation. The bridge die can flexibly include passive devices, active devices, or photonic devices. Thus, the bridge die can serve multiple functions to connect dies through the bridge as well as passively or actively control signals through the bridge die.

One embodiment is a method including mounting a first device die to a carrier. The method also includes mounting a second device die to the carrier. The method also includes surrounding the first device die and the second device die with a first encapsulant. The method also includes thinning the first encapsulant, the first device die, and the second device die to expose a first backside via of the first device die and expose a second backside via of the second device die. The method also includes forming a first bond pad over the first backside via and a second bond pad over the second backside via. The method also includes directly bonding a first metal pad of a bridge die to the first bond pad and a second metal pad of the bridge die to the second bond pad. The method also includes removing the carrier and forming first connectors disposed at a front side of the first device die and the second device die. In an embodiment, directly bonding the first metal pad to the first bond pad includes placing the bridge die on the first device die and the second device die; pressing the first metal pad against the first bond pad; and annealing the combination of the bridge die, the first device die, and the second device die to interdiffuse a metallic material of the first metal pad with a metallic material of the first bond pad. In an embodiment, the method further includes forming a third bond pad interposed between the first bond pad and the second bond pad, the third bond pad aligned to be over the first encapsulant between the first device die and the second device die, the third bond pad being a dummy bond pad. In an embodiment, the bridge die includes an integrated passive device, an active device, or a photonic element. In an embodiment, the method further includes directly bonding a first metal pad of a device die to a third bond pad formed over the first device die. In an embodiment, the bridge die is a first bridge die, and the method further includes directly bonding a third metal pad of a second bridge die to a third bond pad formed over the first device die, and directly bonding a fourth metal pad of the second bridge die to a fourth bond pad formed over a third device die. In an embodiment, the method further includes depositing a second encapsulant over and surrounding the bridge die, and planarizing the second encapsulant and the bridge die. In an embodiment, planarizing the bridge die exposes a third metal via and a fourth metal via of the bridge die, and the method further includes forming a third bond pad on the third metal via and a fourth bond pad on the fourth metal via; aligning a third device die over the third bond pad; aligning a fourth device die over the fourth bond pad; and directly bonding the third device die to the third bond pad and the fourth device die to the fourth bond pad, an interface of the third bond pad and the third device die free from a solder material, the bridge die electrically coupling the third device die to the fourth device die.

Another embodiment is a method including attaching a front side of a first die and a front side of a second die to a carrier substrate. The method also includes encapsulating the first die and the second die by a first encapsulant. The method also includes exposing a first metal feature in the first die and a second metal feature in the second die. The method also includes forming a bonding layer over the first die, the second die, and the first encapsulant. The method also includes depositing a first bond pad over and in contact with the first metal feature and a second bond pad over and in contact with the second metal feature. The method also includes bonding a bridge die to both the first die and the second die, the bridge die electrically coupling the first bond pad to the second bond pad. The method also includes encapsulating the bridge die by a second encapsulant. In an embodiment, an interface between the first bond pad and the bridge die is free from a solder material. In an embodiment, bonding the bridge die includes pressing a front side of the bridge die to the bonding layer, bond pads of the bridge die aligned to bond pads of the bonding layer; and while pressing, performing an annealing process, where material elements from the bridge die interdiffuse with elements from the bonding layer. In an embodiment, the method further includes depositing a third bond pad in the bonding layer, the third bond pad aligned with a portion of the first encapsulant which is disposed between the first die and the second die; and bonding the bridge die to the third bond pad. In an embodiment, the bridge die is a first bridge die, the first bridge die overlapping a first edge of the first die, and the method further includes bonding a second bridge die to the first die and a third die, the second bridge die overlapping an edge of the first die other than the first edge. In an embodiment, the method further includes exposing a third metal feature and a fourth metal feature on a back side of the bridge die; forming a second bonding layer over the bridge die; depositing a third bond pad in the second bonding layer over and in contact with the third metal feature and a fourth bond pad in the second bonding layer over and in contact with the fourth metal feature; and bonding third die to the third bond pad and a fourth die to the fourth bond pad, the bridge die electrically coupling the third bond pad to the fourth bond pad. In an embodiment, the bridge die includes a passive device, an active device, or a photonic element, and the method further includes attaching a wafer to the second encapsulant; removing the carrier substrate; and forming front side connectors on the first die and on the second die.

Another embodiment is a structure including a first device die and a second device die. The structure also includes a first encapsulant laterally surrounding the first device die and the second device die. The structure also includes a bridge die disposed over the first device die and the second device die, the bridge die straddling a portion of the first encapsulant, the bridge die electrically coupling the first device die to the second device die. The structure also includes a bonding interface layer interposed between the bridge die and the first device die and between the bridge die and the second device die. The structure also includes first bond pads and second bond pads disposed in the bonding interface layer, the first bond pads disposed over the first device die, the second bond pads disposed over the second device die, the bridge die coupled to the first bond pads and the second bond pads, where interfaces between the first bond pads and the bridge die are free from solder material.

In an embodiment, the structure further includes third bond pads disposed on the bonding interface layer, the third bond pads being dummy bond pads, the third bond pads disposed over a portion of the first encapsulant, where interfaces between the third bond pads and the bridge die are free from solder material. In an embodiment, the structure further includes a third device die disposed on and electrically coupled to the first device die, and a fourth device die disposed on and electrically coupled to the second device die. In an embodiment, the bridge die is a first bridge die, the first bridge die overlapping a first edge of the first device die; the structure further including a third device die disposed adjacent the first device die, and a second bridge die disposed over both the first device die and the third device die, the second bridge die electrically coupling the first device die and the third device die. In an embodiment, the bridge die includes a passive device, an active device, or a photonic element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A structure comprising:
a first device die and a second device die;
a first encapsulant laterally surrounding the first device die and the second device die;
a bridge die disposed over the first device die and the second device die, the bridge die straddling a portion of the first encapsulant, the bridge die electrically coupling the first device die to the second device die;
a bonding interface layer interposed between the bridge die and the first device die and between the bridge die and the second device die; and
first bond pads and second bond pads disposed in the bonding interface layer, the first bond pads disposed over the first device die, the second bond pads disposed over the second device die, the bridge die coupled to the first bond pads and the second bond pads, wherein interfaces between the first bond pads and the bridge die are free from solder material.

2. The structure of claim 1, further comprising:
third bond pads disposed on the bonding interface layer, the third bond pads being dummy bond pads, the third bond pads disposed over a portion of the first encapsulant, wherein interfaces between the third bond pads and the bridge die are free from solder material.

3. The structure of claim 1, further comprising:
a third device die disposed on and electrically coupled to the first device die; and
a fourth device die disposed on and electrically coupled to the second device die.

4. The structure of claim 1, wherein the bridge die is a first bridge die, the first bridge die overlapping a first edge of the first device die, further comprising:
a third device die disposed adjacent the first device die; and
a second bridge die, disposed over both the first device die and the third device die, the second bridge die electrically coupling the first device die and the third device die.

5. The structure of claim 1, wherein the bridge die includes a passive device, an active device, or a photonic element.

6. The structure of claim 1, further comprising:
an insulating layer between the bonding interface layer and the first device die.

7. The structure of claim 6, wherein the first encapsulant extends along sidewalls of the insulating layer, wherein the first device die comprises a through via, wherein the through via extends through the insulating layer.

8. A structure comprising:
a first device die having a first substrate, a first interconnect structure, and a first through via extending through the first substrate;
a second device die having a second substrate, a second interconnect structure, and a second through via extending through the second substrate;
a first encapsulant laterally encapsulating the first device die and the second device die;
a bonding layer over the first device die, the second device die, and the first encapsulant, wherein an active side of the first device die and an active side of the second device die face away from the bonding layer;
a first bond pad in the bonding layer, wherein the first bond pad directly contacts the first through via;
a second bond pad in the bonding layer, wherein the second bond pad directly contacts the second through via;
a bridge die bonded directly to the first bond pad and the second bond pad, wherein the bridge die comprises a bridge substrate and a bridge interconnect structure, wherein the first bond pad is electrically coupled to the second bond pad through only the bridge interconnect structure; and
a second encapsulant laterally encapsulating the bridge die.

9. The structure of claim 8, wherein the bridge die includes an active device.

10. The structure of claim 8, wherein the bridge die includes a photonic device.

11. The structure of claim 8, wherein the bridge die includes an integrated passive device.

12. The structure of claim 8, further comprising:
an insulating layer on a surface of the first substrate, wherein the insulating layer is between the first substrate and the bonding layer.

13. The structure of claim 12, wherein the insulating layer extends along sidewalls of the first through via.

14. The structure of claim 13, wherein the first encapsulant extends along sidewalls of the insulating layer.

15. The structure of claim 8, wherein the bonding layer separates the first encapsulant and the second encapsulant.

16. A structure comprising:
a first device die having a first conductive feature;
a second device die having a second conductive feature;
a first encapsulant laterally encapsulating the first device die and the second device die;
a first bonding layer over the first device die, the second device die, and the first encapsulant;
a first bond pad and a second bond pad in the first bonding layer, wherein the first bond pad is over and in contact with the first conductive feature, wherein the second bond pad is over and in contact with the second conductive feature;
a bridge die bonded to both the first device die and the second device die, the bridge die electrically coupling the first bond pad to the second bond pad, the bridge die having a third conductive feature and a fourth conductive feature;
a second encapsulant laterally encapsulating the bridge die;
a second bonding layer over the bridge die;
a third bond pad in the second bonding layer over and in contact with the third conductive feature and a fourth bond pad in the second bonding layer over and in contact with the fourth conductive feature; and
a third device die bonded to the third bond pad and a fourth device die bonded to the fourth bond pad, the bridge die electrically coupling the third bond pad to the fourth bond pad.

17. The structure of claim 16, wherein an active side of the first device die faces away from the first bonding layer, wherein the first conductive feature is a through via.

18. The structure of claim 16, further comprising:
a fifth bond pad in the first bonding layer, wherein the fifth bond pad is a dummy bond pad.

19. The structure of claim 18, wherein the dummy bond pad is laterally between the first device die and the second device die.

20. The structure of claim 16, further comprising:
an insulating layer on a surface of the first device die, wherein a surface of the insulating layer is level with a surface of the first encapsulant.
